(19) United States
(12) Patent Application Publication
(10) Pub. No.: US 2020/0027877 A1
(43) Pub. Date: Jan. 23, 2020

(54) SEMICONDUCTOR DEVICE INCLUDING A FIELD EFFECT TRANSISTOR

(71) Applicant: SAMSUNG ELECTRONICS CO., LTD., Suwon-si (KR)

(72) Inventors: JINYOUNG KIM, Hwaseong-si (KR); YURI MASUOKA, Seongnam-si (KR)

(21) Appl. No.: 16/437,169

(22) Filed: Jun. 11, 2019

(30) Foreign Application Priority Data
Jul. 19, 2018 (KR) 10-2018-0083892

(51) Int. Cl. H01L 27/088; H01L 29/06; H01L 29/66; H01L 29/36; H01L 29/78; H01L 21/8234

(52) U.S. Cl. CPC H01L 27/0886; H01L 29/0649; H01L 29/66545; H01L 29/36; H01L 21/823437; H01L 29/66795; H01L 21/823431; H01L 21/823493; H01L 21/823481; H01L 29/7851

(57) ABSTRACT

A semiconductor device includes: a substrate including a first well region; a gate electrode disposed on the substrate; a semiconductor pattern disposed between the substrate and the gate electrode; a plurality of source/drain patterns disposed on the substrate and on opposing sides of the gate electrode; an impurity layer disposed in the substrate and between the semiconductor pattern and the first well region; and a barrier layer disposed in the substrate and between the semiconductor pattern and the impurity layer. The barrier layer includes oxygen.

### CROSS-REFERENCE TO RELATED APPLICATION

This U.S. nonprovisional application claims priority under 35 U.S.C § 119 to Korean Patent Application No. 10-2018-0083892 filed on Jul. 19, 2018 in the Korean Intellectual Property Office, the disclosure of which is incorporated by reference herein in its entirety.

### TECHNICAL FIELD

The present inventive concept relates to a semiconductor device, and more particularly, to a semiconductor device including a field effect transistor.

### DISCUSSION OF THE RELATED ART

A semiconductor device may include an integrated circuit including metal oxide semiconductor field effect transistors (MOSFETs). As the size of the integrated circuits and that of their design rules are decreased, sizes of the MOSFETs are also increasingly scaled down. The scale down of MOSFETs may deteriorate operating characteristics of the semiconductor device. Accordingly, research has been on going to manufacture the semiconductor device having increased performance while overcoming limitations due to increased integration of the semiconductor device.

### SUMMARY

According to an exemplary embodiment of the present inventive concept, a semiconductor device includes: a substrate including a first well region; a gate electrode disposed on the substrate; a semiconductor pattern disposed between the substrate and the gate electrode; a plurality of source/drain patterns disposed on the substrate and on opposing sides of the gate electrode; an impurity layer disposed in the substrate and between the semiconductor pattern and the first well region; and a barrier layer disposed in the substrate and between the semiconductor pattern and the impurity layer. The barrier layer includes oxygen.

According to an exemplary embodiment of the present inventive concept, a semiconductor device includes: a substrate; a gate electrode disposed on the substrate; a semiconductor pattern disposed between the substrate and the gate electrode; a plurality of source/drain patterns disposed on the substrate and on opposing sides of the gate electrode; an impurity layer disposed in the substrate and adjacent to the semiconductor pattern; and a barrier layer disposed in the substrate and between the semiconductor pattern and the impurity layer. The impurity layer includes impurities having a first conductivity type. An impurity concentration of the first conductivity type in an upper portion of the impurity layer is greater than an impurity concentration of the first conductivity type in a lower portion of the impurity layer.

According to an exemplary embodiment of the present inventive concept, a semiconductor device includes: a substrate; a plurality of gate electrodes disposed on the substrate; a semiconductor pattern disposed between the substrate and the gate electrodes; a plurality of source/drain patterns disposed on the substrate, wherein each of the plurality of source/drain patterns is disposed between a pair of gate electrodes of the plurality of gate electrodes; an impurity layer disposed in the substrate and including impurities having a first conductivity type; and a barrier layer disposed in the substrate and between the semiconductor pattern and the impurity layer. The barrier layer is disposed adjacent to an upper surface of the impurity layer.

### BRIEF DESCRIPTION OF THE DRAWINGS

The above and other features of the inventive concept will become more apparent by describing in detail exemplary embodiments thereof, with reference to the accompanying drawings, in which:

FIG. 1 is a plan view illustrating a semiconductor device according to an exemplary embodiment of the present inventive concept;

FIGS. 2A, 2B, and 2C are cross-sectional views respectively taken along lines I-I′, II-II′, and III-III′ of FIG. 1 according to an exemplary embodiment of the present inventive concept;

FIG. 3 is a graph illustrating an impurity concentration in an impurity layer according to an exemplary embodiment of the present inventive concept;

FIGS. 4A, 5A, 6A, 7A, and 8A are cross-sectional views taken along line I-I′ of FIG. 1, illustrating a method of manufacturing a semiconductor device according to an exemplary embodiment of the present inventive concept;

FIGS. 4B, 5B, 6B, 7B, and 8B are cross-sectional views taken along line II-II′ of FIG. 1, illustrating a method of manufacturing a semiconductor device according to an exemplary embodiment of the present inventive concept;

FIGS. 4C,5C, 6C, 7C, and 8C are cross-sectional views taken along line III-III′ of FIG. 1, illustrating a method of manufacturing a semiconductor device according to an exemplary embodiment of the present inventive concept;

FIGS. 9A, 9B, and 9C are cross-sectional views respectively taken along lines I-I′, II-II′, and III-II′ of FIG. 1, illustrating a semiconductor device according to an exemplary embodiment of the present inventive;

FIGS. 10A, 11A, and 12A are cross-sectional views taken along line I-I′ of FIG. 1, illustrating a method of manufacturing a semiconductor device according to an exemplary embodiment of the present inventive concept;

FIGS. 10B, 11B, and 12B are cross-sectional views taken along line II-II′ of FIG. 1, illustrating a method of manufacturing a semiconductor device according to an exemplary embodiment of the present inventive concept;

FIGS. 10C, 11C, and 12C are cross-sectional views taken along line III-III′ of FIG. 1, illustrating a method of manufacturing a semiconductor device according to an exemplary embodiment of the present inventive concept;

FIGS. 13A, 13B, and 13C are cross-sectional views respectively taken along lines I-I′, II-II′, and III-III′ of FIG. 1, illustrating a semiconductor device according to an exemplary embodiment of the present inventive concept;

FIGS. 14A, 15A and 16A are cross-sectional views taken along line I-I′ of FIG. 1, illustrating a method of manufacturing a semiconductor device according to an exemplary embodiment of the present inventive concept;

FIGS. 14B, 15B and 16B are cross-sectional views taken along line II-II′ of FIG. 1, illustrating a method of manufacturing a semiconductor device according to an exemplary embodiment of the present inventive concept; and

FIGS. 14C, 15C and 16C are cross-sectional views taken along line III-II′ of FIG. 1, illustrating a method of manufacturing a semiconductor device according to an exemplary embodiment of the present inventive concept.

### DETAILED DESCRIPTION OF EMBODIMENTS

Exemplary embodiments of the present inventive concept will be described in more detail below with reference to the accompanying drawings, in which exemplary embodiments of the preset inventive concept are shown.

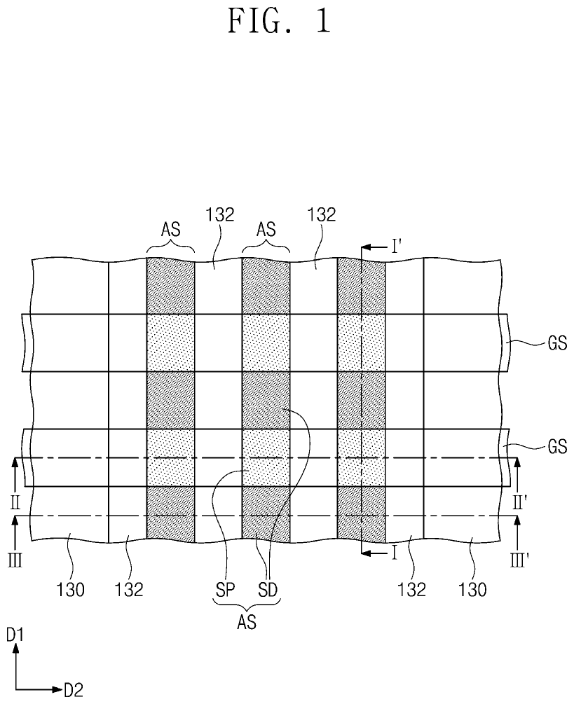

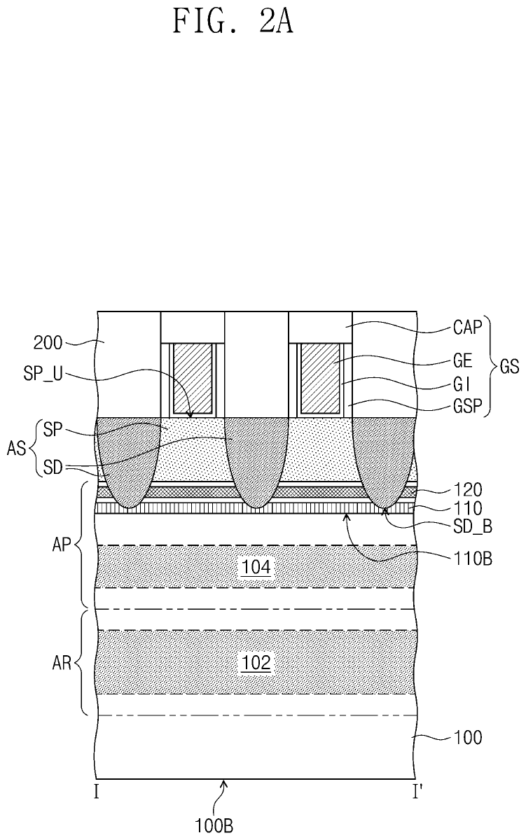

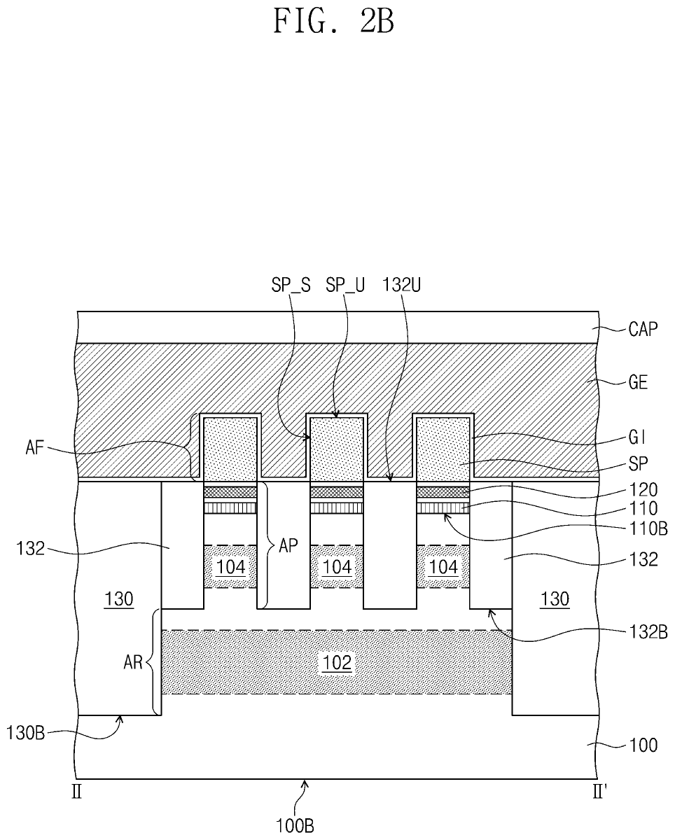

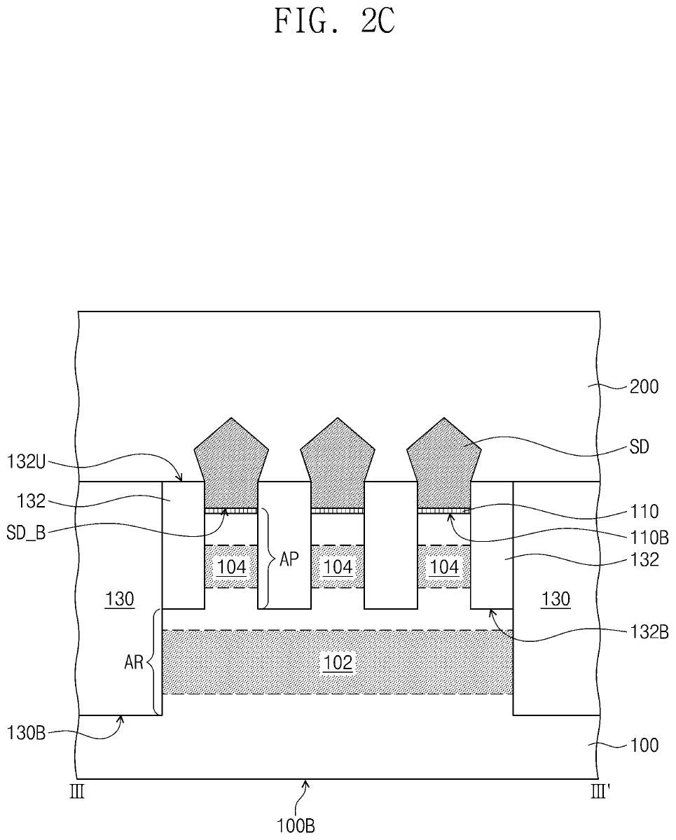

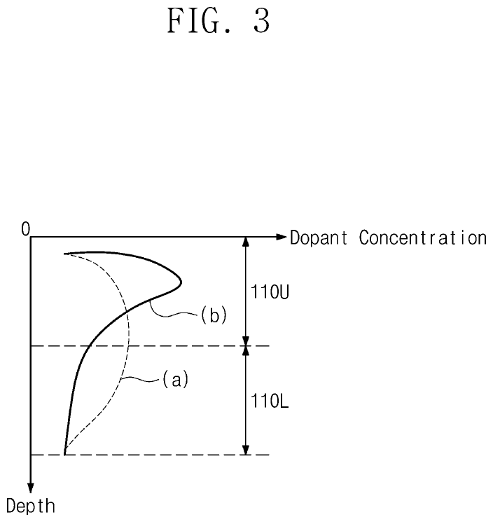

FIG. 1 is a plan view illustrating a semiconductor device according to an exemplary embodiment of the present inventive concept. FIGS. 2A, 2B, and 2C are cross-sectional views respectively taken along lines I-I′, II-II′, and III-III′ of FIG. 1 according to an exemplary embodiment of the present inventive concept. FIG. 3 is a graph illustrating an impurity concentration in an impurity layer according to an exemplary embodiment of the present inventive concept.

Referring to FIGS. 1 and 2A to 2C, a substrate 100 may include an active region AR and a plurality of active patterns AP protruding from the active region AR. The active patterns AP may extend in a first direction D1 on the active region AR, and each active pattern AP may be spaced apart from each other in a second direction D2 intersecting the first direction D1. The first and second directions D1 and D2 may extend parallel to a bottom surface 100B of the substrate 100. The substrate 100 may be, for example, a silicon substrate, a germanium substrate, a silicon-germanium substrate, or a silicon-on-insulator (SOI) substrate.

The substrate 100 may include first device isolation patterns 130 defining the active region AR. The first device isolation patterns 130 may be disposed on corresponding lateral surfaces of the active region AR. For example, the first device isolation patterns 130 may contact corresponding lateral surfaces of the active region AR. The substrate 100 may further include second device isolation patterns 132 defining the active patterns AP. The second device isolation patterns 132 may be disposed on the active region AR. The second device isolation patterns 132 may extend in the first direction D1 on the active region AR, and each of the second device isolation patterns 132 may be spaced apart from each other in the second direction D2. The second device isolation patterns 132 and the active patterns AP may be disposed alternately in the second direction D2 on the active region AR. A pair of the second device isolation patterns 132 may be disposed on corresponding opposite lateral surfaces of each of the active patterns AP. For example, each second device isolation pattern 132 may be disposed between each pair of active patterns AP. The first device isolation patterns 130 may be deeper than the second device isolation patterns 132. For example, the first device isolation patterns 130 may have their bottom surfaces 130B at a lower height than that of bottom surfaces 132B of the second device isolation patterns 132. In this description, for example, the term “height” may indicate a distance from the bottom surface 100B of the substrate 100. The first device isolation patterns 130 and the second device isolation patterns 132 may be connected to each other and may constitute portions of one dielectric layer. The first device isolation patterns 130 and the second device isolation patterns 132 may include, for example, oxide, nitride, or oxynitride.

A first well region 102 may be disposed in the active region AR of the substrate 100. The first well region 102 may be an impurity region where the substrate 100 is doped with dopants (or, e.g., impurities) having a first conductivity type. For example, the first well region 102 may have the first conductivity type. For example, when the first conductivity type is N-type, the dopants having the first conductivity type may be, for example, phosphorous (P). For example, the first conductivity type is P-type, the dopants having the first conductivity type may be, for example, boron (B).

A second well region 104, an impurity layer 110, and a barrier layer 120 may be disposed in each of the active patterns AP. The second well region 104 may be disposed at a lower portion of each of the active patterns AP, and the impurity layer 110 and the barrier layer 120 may be disposed at an upper portion of each of the active patterns AP. The impurity layer 110 may be interposed between the second well region 104 and the barrier layer 120. For example, the second well region 104 may be disposed on the active region AR, the impurity layer 110 may be disposed on the second well region 104, and the barrier layer 120 may be disposed on the impurity layer 110. The second well region 104 may be an impurity region where the substrate 100 is doped with dopants having the first conductivity type. The second well region 104 may have the same conductivity type as that of the first well region 102. According to an exemplary embodiment of the present inventive concept, a dopant concentration of the first conductivity type in the second well region 104 may be substantially the same as a dopant concentration of the first conductivity type in the first well region 102.

The impurity layer 110 may be an impurity region where the substrate 100 is doped with dopants having the first conductivity type. The impurity layer 110 may have the same conductivity type as that of the first and second well regions 102 and 104. A dopant concentration of the first conductivity type in the impurity layer 110 may be greater than a dopant concentration of the first conductivity type in each of the first and second well regions 102 and 104. The barrier layer 120 may be disposed in the substrate 100 and may include oxygen atoms. For example, the barrier layer 120 may include silicon oxide. The barrier layer 120 may act as a diffusion break layer that may prevent diffusion of the dopants having the first conductivity type in the impurity layer 110.

Referring to FIG. 3, a dotted line (a) may express a concentration distribution of the dopants having the first conductivity type in the impurity layer 110 prior to an annealing process, and a solid line (b) may denote a concentration distribution of the dopants having the first conductivity type in the impurity layer 110 after the annealing process. The annealing process may cause diffusion of the dopants having the first conductivity type in the impurity layer 110, and the barrier layer 120 may prevent diffusion of the dopants having the first conductivity type. As a result, the dopants having the first conductivity type may diffuse from a lower portion 110L of the impurity layer 110, and may then be piled up in an upper portion 110U of the impurity layer 110. For example, the upper portion 110U may be adjacent to an upper surface of the impurity layer 110, and the lower portion 110L may be adjacent to a lower surface of the impurity layer 110. The impurity layer 110 may be configured such that the upper portion 110U may be closer than the lower portion 110L to the barrier layer 120. Accordingly, as expressed by the solid line (b), the dopant concentration of the first conductivity type in the impurity layer 110 may have a maximum value at the upper portion 110U of the impurity layer 110.

Referring to FIGS. 1 and 2A to 2C, active structures AS may be provided on the substrate 100. The active structures AS may be disposed on corresponding active patterns AP. The active structures AS may extend in the first direction D1 and may be spaced apart from each other in the second direction D2. Each of the active structures AS may include a semiconductor pattern SP and source/drain patterns SD. The source/drain patterns SD may be spaced apart in the first direction D1 from each other across the semiconductor pattern SP extending in the first direction D1. For example, the semiconductor pattern SP may be disposed between each of the source/drain patterns SD.

The semiconductor pattern SP may be an epitaxial pattern grown from the substrate 100 serving as a seed. The semiconductor pattern SP may include an intrinsic semiconductor material. For example, the semiconductor pattern SP may include undoped silicon. The source/drain patterns SD may be epitaxial patterns grown from the substrate 100 serving as a seed. The source/drain patterns SD may include, for example, at least one of silicon germanium (SiGe), silicon (Si), and/or silicon carbide (SiC). The source/drain patterns SD may further include dopants having a second conductivity type. The source/drain patterns SD may have the second conductivity type, which may be different from the first conductivity type. For example, the source/drain patterns SD may have a different conductivity type from that of the impurity layer 110 and that of the first and second well regions 102 and 104. For example, when the first conductivity type is N-type, the second conductivity type may be P-type, and when the first conductivity type is P-type, the second conductivity type may be N-type. The dopants having the second conductivity type may be different from the dopants having the first conductivity type. For example, when the second conductivity type is N-type, the dopants having the second conductivity type may be, for example, phosphorous (P). For example, when the second conductivity type is P-type, the dopants having the second conductivity type may be, for example, boron (B).

The barrier layer 120 may be interposed between the impurity layer 110 and the semiconductor pattern SP. In an exemplary embodiment of the present inventive concept, each of the source/drain patterns SD may contact of the impurity layer 110 and/or the barrier layer 120. For example, each of the source/drain patterns SD may penetrate the barrier layer 120 and contact the impurity layer 110. In this case, at least a portion of the impurity layer 110 may extend between each of the source/drain patterns SD. In addition, the impurity layer 110 may be between the second well region 104 and the source/drain patterns SD. For example, each of the source/drain patterns SD may have a lowermost bottom surface SD_B at a greater height than that of a bottom surface 110B of the impurity layer 110. However, the present inventive concept is not limited thereto. For example, the lowermost bottom surface SD_B of each of the source/drain patterns SD may be located at substantially the same height as that of the bottom surface 110B of the impurity layer 110.

The second device isolation patterns 132 may be disposed on corresponding opposite sides of each of the active structures AS. The second device isolation patterns 132 may expose the semiconductor pattern SP and also expose an upper portion of each of the source/drain patterns SD. An active fin AF may include the semiconductor pattern SP exposed by the second device isolation patterns 132. The second device isolation patterns 132 may have their top surfaces 132U at a lower height than that of a top surface SP_U of the semiconductor pattern SP, and may expose lateral surfaces SP_S of the semiconductor pattern SP. The first device isolation patterns 130 may have their top surfaces at substantially the same height as that of the top surfaces 132U of the second device isolation patterns 132, but the present inventive concept is not limited thereto.

A gate structure GS disposed on the substrate 100 may extend across the active structures AS. The gate structure GS may extend in the second direction D2 and may cover the semiconductor pattern SP of each of the active structures AS. The gate structure GS may cover the top and lateral surfaces SP_U and SP_S of the semiconductor pattern SP, and may extend in the second direction D2 to cover the top surfaces 132U of the second device isolation patterns 132. The source/drain patterns SD may be disposed on opposite sides of the gate structure GS, respectively. The gate structure GS may be provided in plural, and in this case, the plurality of gate structures GS may extend in the second direction D2 and may be spaced apart from each other in the first direction D1.

The gate structure GS may include a gate electrode GE extending in the second direction D2, a gate dielectric pattern GI between the gate electrode GE and the semiconductor pattern SP, a gate capping pattern CAP on a top surface of the gate electrode GE, and gate spacers GSP on lateral surfaces of the gate electrode GE. The gate electrode GE may cover the top and lateral surfaces SP_U and SP_S of the semiconductor pattern SP, and may extend in the second direction D2 to cover the top surfaces 132U of the second device isolation patterns 132. The gate dielectric pattern GI may extend along a bottom surface of the gate electrode GE. The gate dielectric pattern GI may be interposed between the gate electrode GE and the top surface SP_U of the semiconductor pattern SP and between the gate electrode GE and each of the lateral surfaces SP_S of the semiconductor pattern SP. The gate dielectric pattern GI may extend between the gate electrode GE and each of the top surfaces 132U of the second device isolation patterns 132. The gate dielectric pattern GI may extend from the bottom surface of the gate electrode GE toward a gap between the gate electrode GE and the gate spacer GSP. The gate spacers GSP may extend in the second direction D2 along the lateral surfaces of the gate electrode GE, and the gate capping pattern CAP may extend in the second direction D2 along the top surface of the gate electrode GE.

The gate electrode GE may include a doped semiconductor, a conductive metal nitride (e.g., titanium nitride, tantalum nitride, etc.), and/or a metal (aluminum, tungsten, etc.). The gate dielectric pattern GI may include one or more of high-k dielectric layers. For example, the gate dielectric pattern GI may include hafnium oxide, hafnium silicate, zirconium oxide, and/or zirconium silicate. The gate capping pattern CAP and the gate spacers GSP may include a nitride (e.g., silicon nitride).

The gate electrode GE, the semiconductor pattern SP, and the source/drain patterns SD may constitute a transistor. The semiconductor pattern SP (or, e.g., the active fin AF) may act as a channel of the transistor. When the transistor is an NMOSFET, the first conductivity type of the first and second well regions 102 and 104 and the impurity layer 110 may be P-type, and the second conductivity type of the source/drain patterns SD may be N-type. In this case, the source/drain patterns SD may be configured to provide the semiconductor pattern SP with tensile strain. When the transistor is a PMOSFET, the first conductivity type of the first and second well regions 102 and 104 and the impurity layer 110 may be N-type, and the second conductivity type of the source/drain patterns SD may be P-type. In this case, the source/drain patterns SD may be configured to provide the semiconductor pattern SP with compressive strain.

When the transistor uses an intrinsic semiconductor pattern as a channel, a resistance distribution of the transistor may be increased to drive the transistor to operate at a low voltage; however, the transistor may be vulnerable to short channel effect resulting from diffusion of dopants in the source/drain patterns SD.

According to an exemplary embodiment of the present inventive concept, the impurity layer 110 and the barrier layer 120 may be disposed adjacent to the semiconductor pattern SP and the source/drain patterns SD. For example, the impurity layer 110 may be a region where the substrate 100 is heavily doped with dopants (e.g., dopants having the first conductivity type) whose conductivity type is different from that of the source/drain patterns SD, and the barrier layer 120 may include oxygen atoms. The barrier layer 120 may act as a diffusion break layer that may prevent diffusion of the dopants having the first conductivity type in the impurity layer 110, and thus the dopants having the first conductivity type in the impurity layer 110 may be piled up in the upper portion 110U of the impurity layer 110. As a result, the dopant concentration of the first conductivity type in the impurity layer 110 may have a maximum value at the upper portion 110U of the impurity layer 110. The impurity layer 110 and the barrier layer 120 may suppress diffusion of the dopants having the second conductivity type in the source/drain patterns SD. Therefore, it may be possible to suppress the short channel effect of the transistor and to prevent the diffusion of the dopants to the source/drain patterns SD.

An interlayer dielectric layer 200 may be disposed on the substrate 100 and may cover the active structures AS and the gate structure GS. The interlayer dielectric layer 200 may cover top surfaces of the first and second device isolation patterns 130 and 132. The interlayer dielectric layer 200 may include source/drain contacts and a gate contact. For example, the interlayer dielectric layer 200 may be connected to corresponding source/drain patterns SD, and may be connected to the gate electrode GE. The source/drain contacts and the gate contact may apply a voltage respectively to the source/drain patterns SD and the gate electrode GE. The interlayer dielectric layer 200 may include, for example, an oxide, a nitride, or an oxynitride.

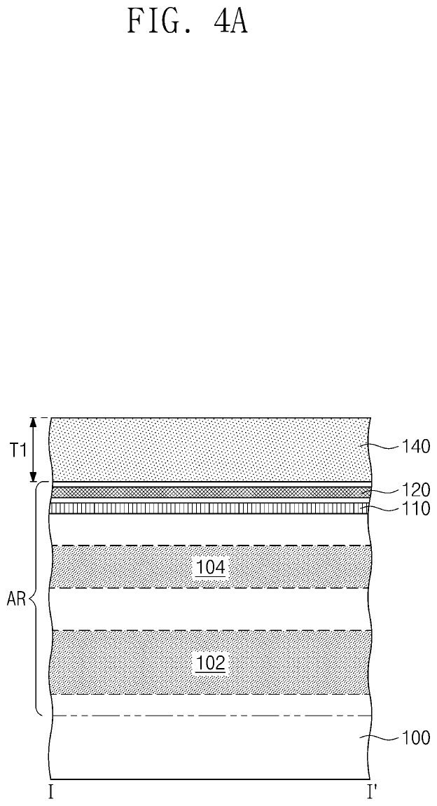

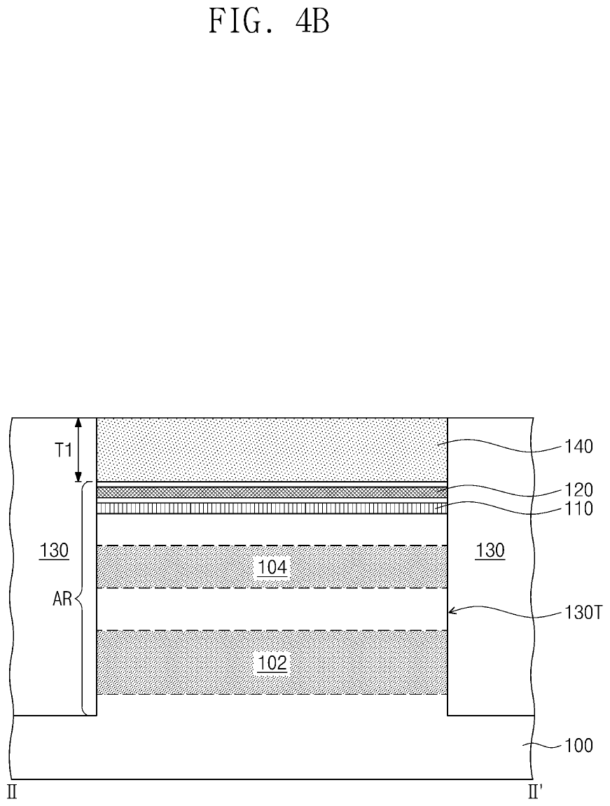

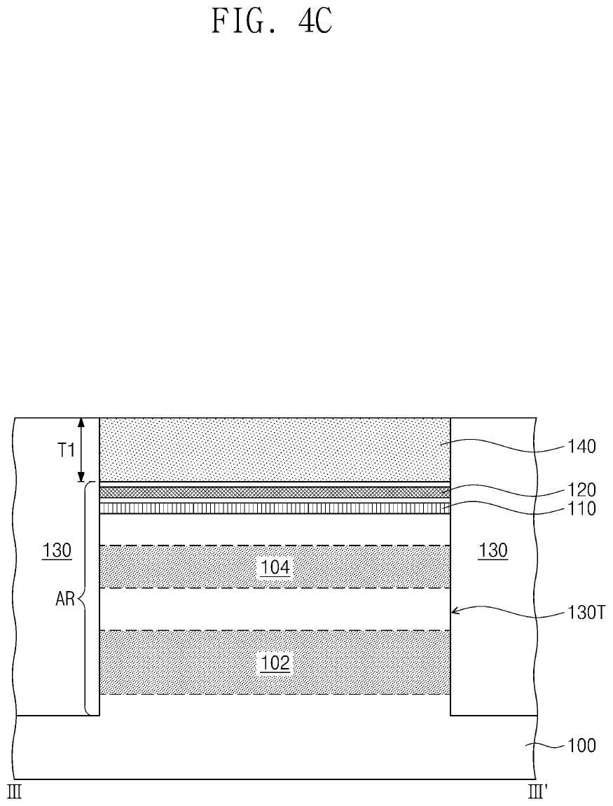

FIGS. 4A to 8A are cross-sectional views taken along line I-I′ of FIG. 1, illustrating a method of manufacturing a semiconductor device according to exemplary embodiment of the present inventive concept. FIGS. 4B to 8B are cross-sectional views taken along line II-II′ of FIG. 1, illustrating a method of manufacturing a semiconductor device according to an exemplary embodiment of the present inventive concept. FIGS. 4C to 8C are cross-sectional views taken along line III-III′ of FIG. 1, illustrating a method of manufacturing a semiconductor device according to an exemplary embodiment of the present inventive concept. The descriptions described below that may be the same or similar as that of the semiconductor device discussed with reference to FIGS. 1 and 2A to 2C may be omitted to the extent that the details omitted may be at least similar to corresponding elements already discussed.

Referring to FIGS. 1 and 4A to 4C, a first well region 102, a second well region 104, an impurity layer 110, and a barrier layer 120 may be sequentially formed in a substrate 100. The first well region 102 and the second well region 104 may be formed by doping the substrate 100 with dopants having a first conductivity type, for example, by performing an ion implantation process. A dopant concentration of the first conductivity type in the second well region 104 may be substantially the same as a dopant concentration of the first conductivity type in the first well region 102. The impurity layer 110 may be formed by doping the substrate 100 with dopants having the first conductivity type, for example, by performing an ion implanting process. A dopant concentration of the first conductivity type in the impurity layer 110 may have be greater than the dopant concentration of the first conductivity type in each of the first and second well regions 102 and 104. The barrier layer 120 may be formed by using, for example, an ion implantation process in which the substrate 100 is implanted with oxygen atoms. The impurity layer 110 and the barrier layer 120 may be formed adjacent to a surface of the substrate 100.

As discussed with reference to FIG. 3, the dopant concentration of the first conductivity type in the impurity layer 110 may be distributed as expressed by the dotted line (a). The dopants having the first conductivity type in the impurity layer 110 may diffuse when a subsequent annealing process is performed, and the barrier layer 120 may prevent diffusion of the dopants having the first conductivity type. As a result, the dopants having the first conductivity type may diffuse from the lower portion 110L of the impurity layer 110, and may then be piled up in the upper portion 110U of the impurity layer 110. After the subsequent annealing process, the dopant concentration of the first conductivity type in the impurity layer 110 may be distributed as expressed by the solid line (b) shown in FIG. 3.

A semiconductor layer 140 may be formed on the substrate 100. The formation of the semiconductor layer 140 may include performing a selective epitaxial growth process in which the substrate 100 is used as a seed. The semiconductor layer 140 may include an intrinsic semiconductor material. For example, the semiconductor layer 140 may include undoped silicon. In an exemplary embodiment of the present inventive concept, the semiconductor layer 140 may have a first thickness T1.

According to an exemplary embodiment of the present inventive concept, first device isolation patterns 130 may be formed in the semiconductor layer 140 and in the substrate 100. The formation of the first device isolation patterns 130 may include forming first trenches 130T to penetrate the semiconductor layer 140 and a portion of the substrate 100, forming a first device isolation layer on the semiconductor layer 140 to fill the first trenches 130T, and performing a planarization process on the first device isolation layer until a top surface of the semiconductor layer 140 is exposed. The first trenches 130T may define an active region AR of the substrate 100. The first well region 102, the second well region 104, the impurity layer 110, and the barrier layer 120 may be sequentially disposed in the active region AR, and the semiconductor layer 140 may be disposed on the active region AR.

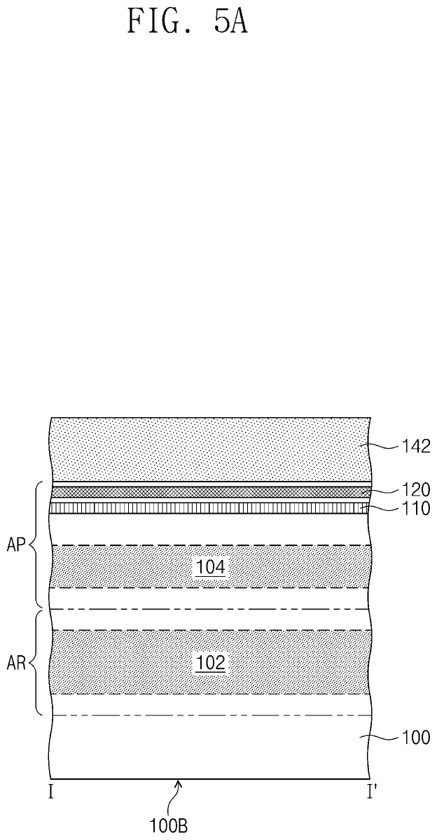

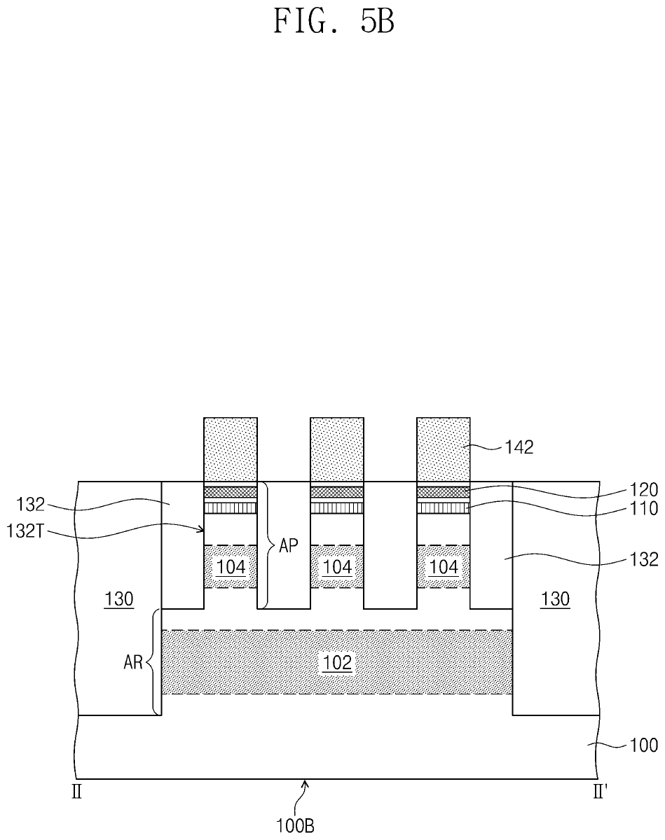

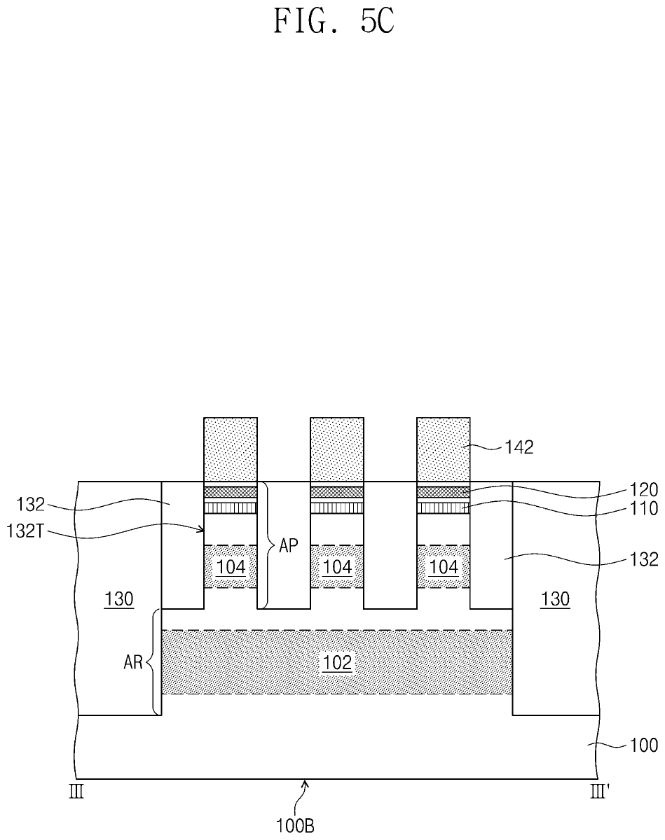

Referring to FIGS. 1 and 5A to 5C, second device isolation patterns 132 may be formed in the semiconductor layer 140 and in the active region AR. The formation of the second device isolation patterns 132 may include forming second trenches 132T to penetrate the semiconductor layer 140 and an upper portion of the active region AR. The second trenches 132T may separate the semiconductor layer 140 into preliminary semiconductor patterns 142, and also separate the upper portion of the active region AR into active patterns AP. The active patterns AP may extend in a first direction D1 and may be spaced apart from each other in a second direction D2 (e.g., crossing the first direction D1). The first and second directions D1 and D2 may be parallel to a bottom surface 100B of the substrate 100 and may intersect each other. Each of the active patterns AP may protrude upwardly from a lower portion of the active region AR. For example, the first well region 102 may be disposed in the lower portion of the active region AR, and the second well region 104, the impurity layer 110, and the barrier layer 120 may be sequentially disposed in each of the active patterns AP on the first well region 102. The preliminary semiconductor patterns 142 may be disposed on corresponding active patterns AP. The preliminary semiconductor patterns 142 may extend in the first direction D1 and may be spaced apart from each other in the second direction D2.

The formation of the second device isolation patterns 132 may include forming a second device isolation layer on the substrate 100 to fill the second trenches 132T, and performing a planarization process on the second device isolation layer until top surfaces of the preliminary semiconductor patterns 142 are exposed. According to an exemplary embodiment of the present inventive concept, upper portions of the first and second device isolation patterns 130 and 132 may be recessed to expose the preliminary semiconductor patterns 142.

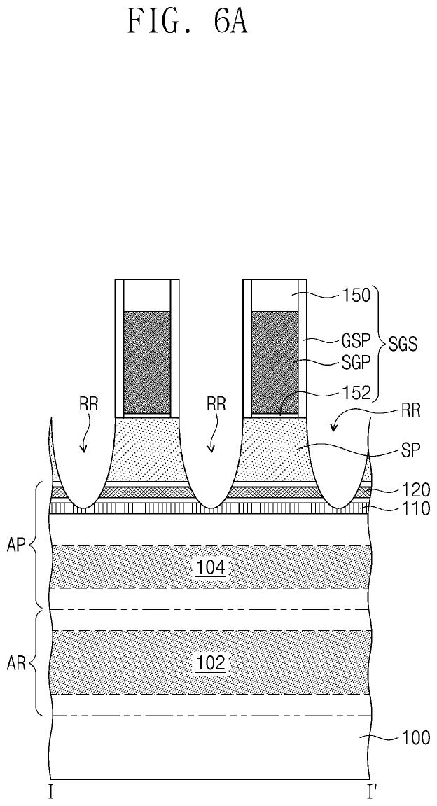

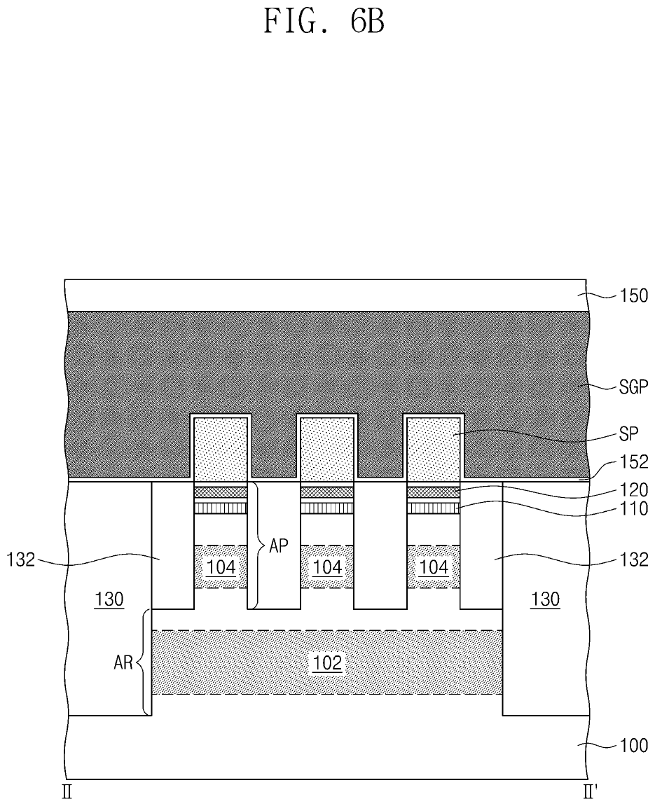

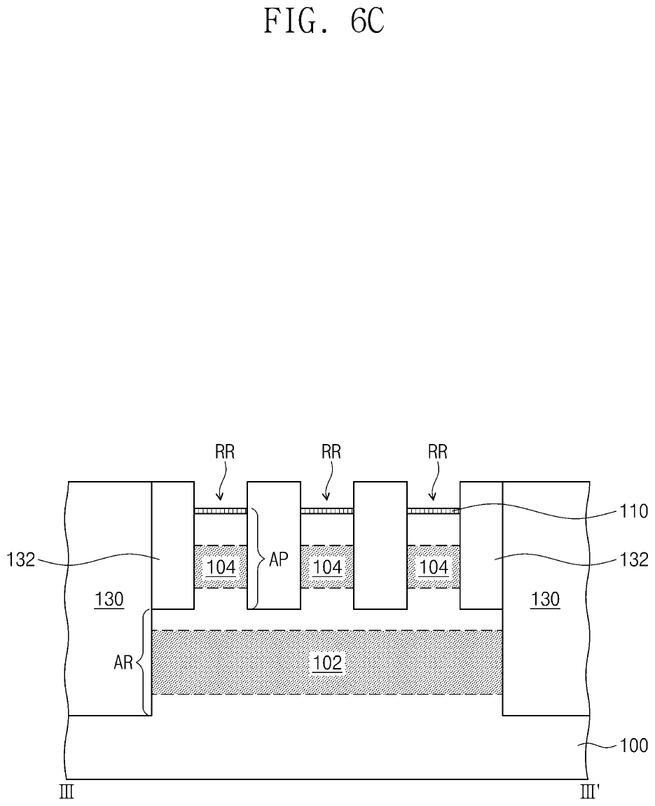

Referring to FIGS. 1 and 6A to 6C, a sacrificial gate structure SGS may extend across the preliminary semiconductor patterns 142 and the first and second device isolation patterns 130 and 132. The sacrificial gate structure SGS may extend in the second direction D2. The sacrificial gate structure SGS may include a sacrificial gate pattern SGP extending in the second direction D2, an etch stop pattern 152 extending along a bottom surface of the sacrificial gate pattern SGP, a mask pattern 150 disposed on a top surface of the sacrificial gate pattern SGP, and gate spacers GSP disposed on lateral surfaces of the sacrificial gate pattern SGP. For example, the formation of the sacrificial gate structure SGS may include forming an etch stop layer on the substrate 100 to cover the preliminary semiconductor patterns 142 and the first and second device isolation patterns 130 and 132, forming a sacrificial gate layer on the etch stop layer, forming the mask pattern 150 on the sacrificial gate layer, and sequentially etching the sacrificial gate layer and the etch stop using the mask pattern 150 as an etching mask. The sacrificial gate layer and the etch stop layer may be etched to respectively form the sacrificial gate pattern SGP and the etch stop pattern 152. The formation of the sacrificial gate structure SGS may further include forming the gate spacers GSP on the lateral surfaces of the sacrificial gate pattern SGP. For example, the formation of the gate spacers GSP may include forming a spacer layer on the substrate 100 to cover the mask pattern 150, the sacrificial gate pattern SGP, and the etch stop pattern 152, and then anisotropically etching the spacer layer. The etch stop pattern 152 may include, for example, silicon oxide, and the sacrificial gate pattern SGP may include, for example, polycrystalline silicon. The mask pattern 150 and the gate spacers GSP may include, for example, nitride (e.g., silicon nitride).

The sacrificial gate structure SGS may be used as an etching mask to pattern each of the preliminary semiconductor patterns 142. Accordingly, recess regions RR may be formed on opposite sides of the sacrificial gate structure SGS, and a semiconductor pattern SP may be formed below the sacrificial gate structure SGS. For example, the recess regions RR may be disposed between each of the sacrificial gate structures SGS. The recess regions RR may expose lateral surfaces of the semiconductor pattern SP. According to an exemplary embodiment of the present inventive concept, each of the active patterns AP may be recessed during the formation of the recess regions RR. Each of the recess regions RR may expose the impurity layer 110 and/or the barrier layer 120. For example, each of the recess regions RR may penetrate the barrier layer 120 and expose the impurity layer 110. For example, each of the recess regions RR may partially penetrate the impurity layer 110.

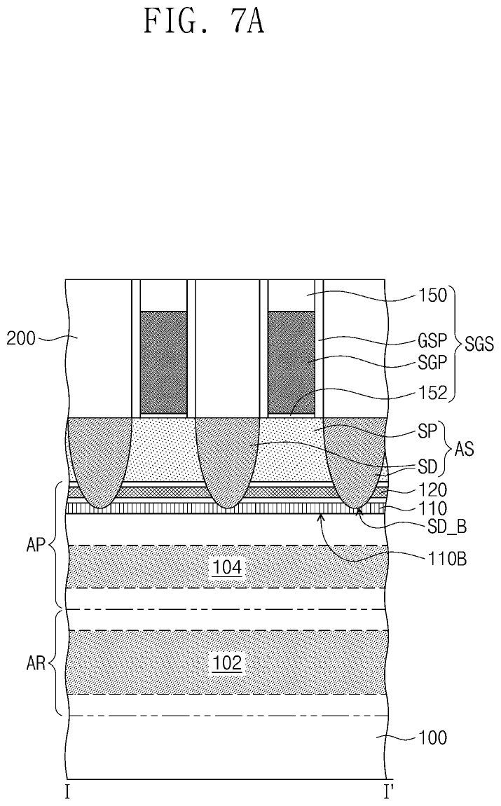

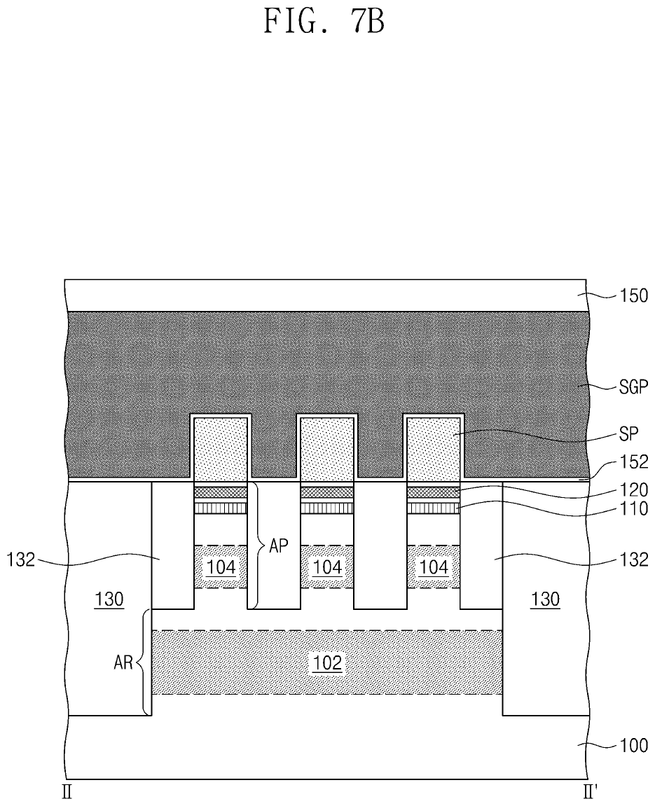

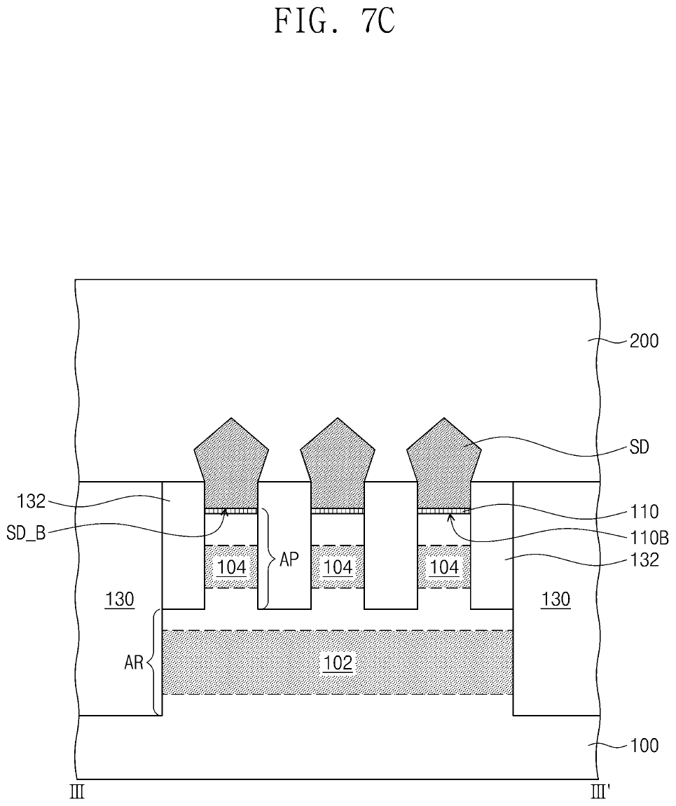

Referring to FIGS. 1 and 7A to 7C, source/drain patterns SD may be formed in corresponding recess regions RR. The formation of the source/drain patterns SD may include performing a selective epitaxial growth process in which the semiconductor pattern SP and each of the active patterns AP are used as seeds. The source/drain patterns SD may include, for example, one or more of silicon germanium (SiGe), silicon (Si), and silicon carbide (SiC). The formation of the source/drain patterns SD may further include implanting the source/drain patterns SD with dopants having a second conductivity type during or after the selective epitaxial growth process. The dopants having the second conductivity type may be different from the dopants having the first conductivity type. For example, when the first conductivity type is N-type, the second conductivity type may be P-type, and when the first conductivity type is P-type, the second conductivity type may be N-type.

According to an exemplary embodiment of the present inventive concept, each of the source/drain patterns SD may contact the impurity layer 110 and/or the barrier layer 120. Each of the source/drain patterns SD may penetrate the barrier layer 120 and contact the impurity layer 110. For example, each of the source/drain patterns SD may partially penetrate the impurity layer 110. For example, each of the source/drain patterns SD may have a lowermost bottom surface SD_B at a greater height than that of a bottom surface 110B of the impurity layer 110 with respect to the substrate 100. However, the present inventive concept is not limited thereto. For example, the lowermost bottom surface SD_B of each of the source/drain patterns SD may be located at substantially the same height as that of the bottom surface 110B of the impurity layer 110.

The source/drain patterns SD may be disposed on opposite sides of the sacrificial gate structure SGS, and may be spaced apart in the first direction D1 from each other across the semiconductor pattern SP. For example, the source/drain patterns SD may be disposed between each of the sacrificial gate structures SGS. The source/drain patterns SD and the semiconductor pattern SP may constitute an active structure AS. An interlayer dielectric layer 200 may be formed on the substrate 100, covering the sacrificial gate structure SGS and the active structure AS.

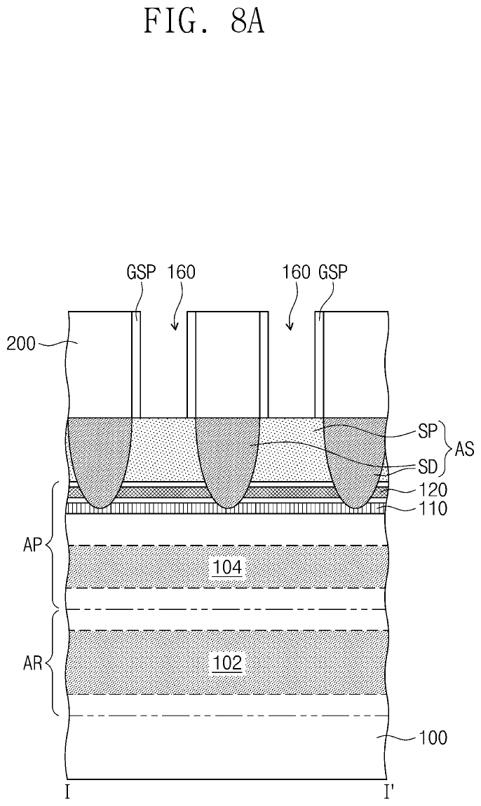

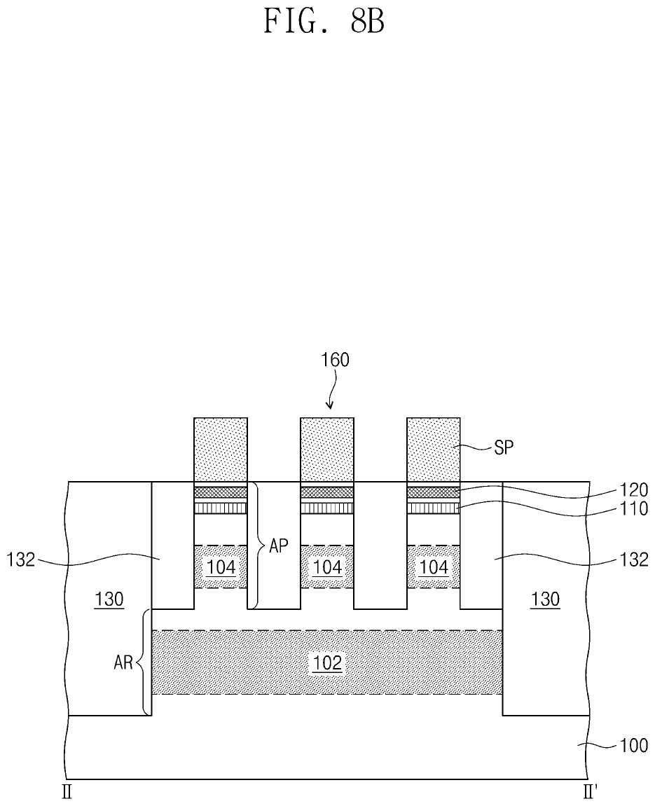

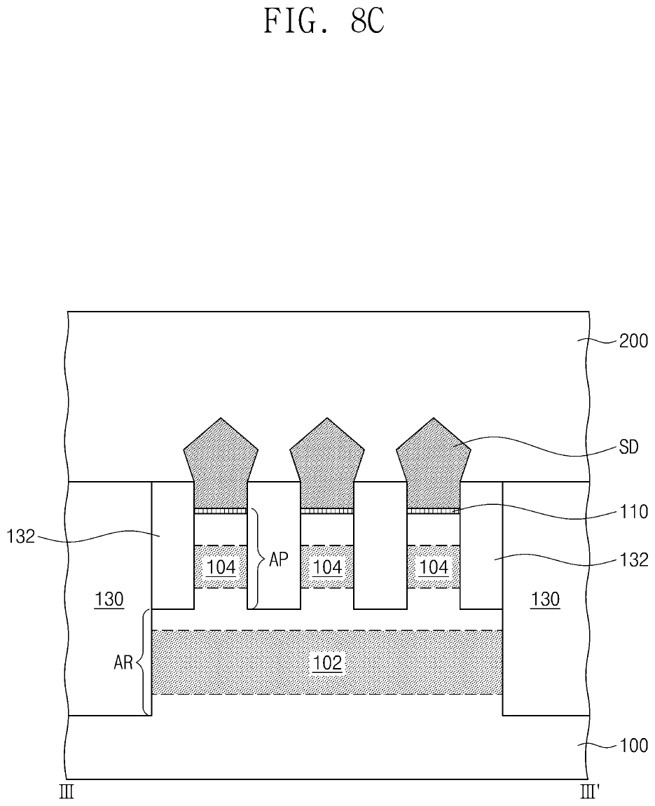

Referring to FIGS. 1 and 8A to 8C, a gap 160 may be formed in the interlayer dielectric layer 200. The gap 160 may be formed by removing the mask pattern 150, the sacrificial gate pattern SGP, and the etch stop pattern 152. For example, the formation of the gap 160 may include performing a planarization process on the interlayer dielectric layer 200, the mask pattern 150, and the gate spacer GSP until the sacrificial gate pattern SGP is exposed. The formation of the gap 160 may further include removing the sacrificial gate pattern SGP by performing an etching process that has an etch selectivity with respect to the etch stop pattern 152 and the gate spacer GSP, and removing the etch stop pattern 152 by performing an etching process that has an etch selectivity with respect to the semiconductor pattern SP and the gate spacer GSP. The gap 160 may expose an inner surface of the gate spacer GSP which was in contact with the sacrificial gate structure SGS. The gap 160 may expose top and lateral surfaces of the semiconductor pattern SP and also expose top surfaces of the first and second device isolation patterns 130 and 132.

Referring to FIGS. 1 and 2A to 2C, a gate structure GS may be formed in the gap 160. For example, the formation of the gate structure GS may include sequentially forming a gate dielectric layer and a gate electrode layer on the interlayer dielectric layer 200 to fill the gap 160. The formation of the gate structure GS may further include performing a planarization process on the gate dielectric layer and the gate electrode layer to form a gate dielectric pattern GI and a gate electrode GE, and forming a gate capping pattern CAP on a top surface of the gate electrode GE in the gap 160. For example, the formation of the gate capping pattern CAP may include forming an empty space in the interlayer dielectric layer 200 by recessing upper portions of the gate electrode GE, the gate dielectric pattern GI, and the gate spacer GSP, forming a gate capping layer on the interlayer dielectric layer 200 to fill the empty space which overlaps each of the upper portions of the gate electrode GE, and performing a planarization process on the gate capping layer until the interlayer dielectric layer 200 is exposed.

According to an exemplary embodiment of the present inventive concept, source/drain contacts may be formed in the interlayer dielectric layer 200. The formation of the source/drain contacts may include forming contact holes in the interlayer dielectric layer 200 to expose corresponding source/drain patterns SD, forming a conductive layer on the interlayer dielectric layer 200 to fill the contact holes, and performing a planarization process on the conductive layer until the interlayer dielectric layer 200 is exposed. A gate contact may be formed on the interlayer dielectric layer 200 to come into connection with the gate electrode GE.

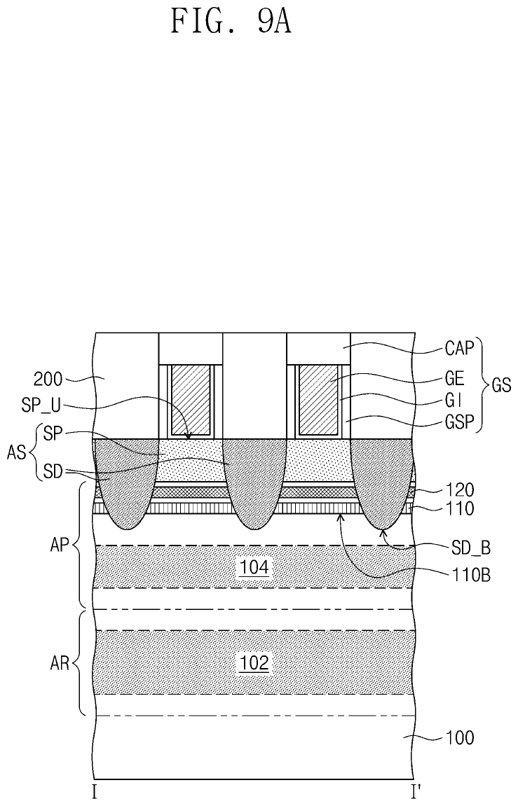

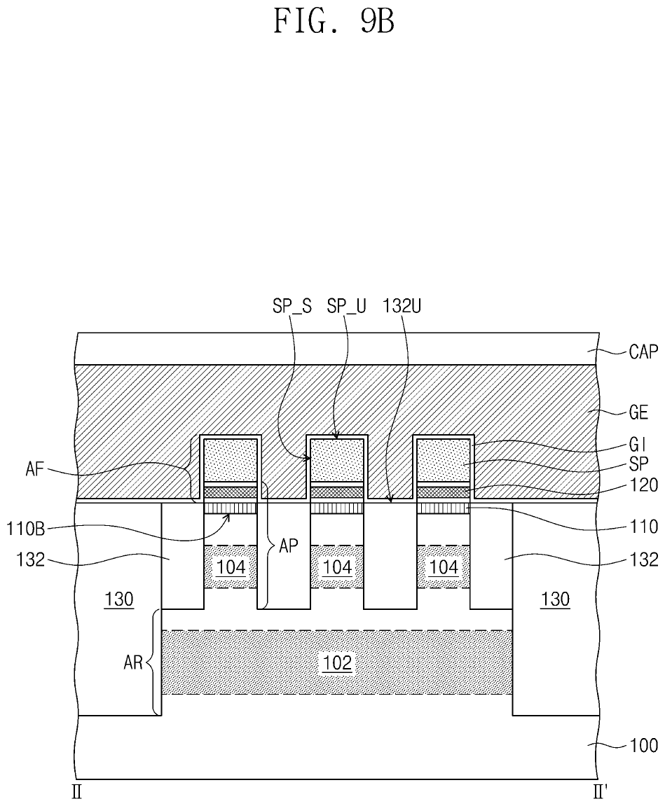

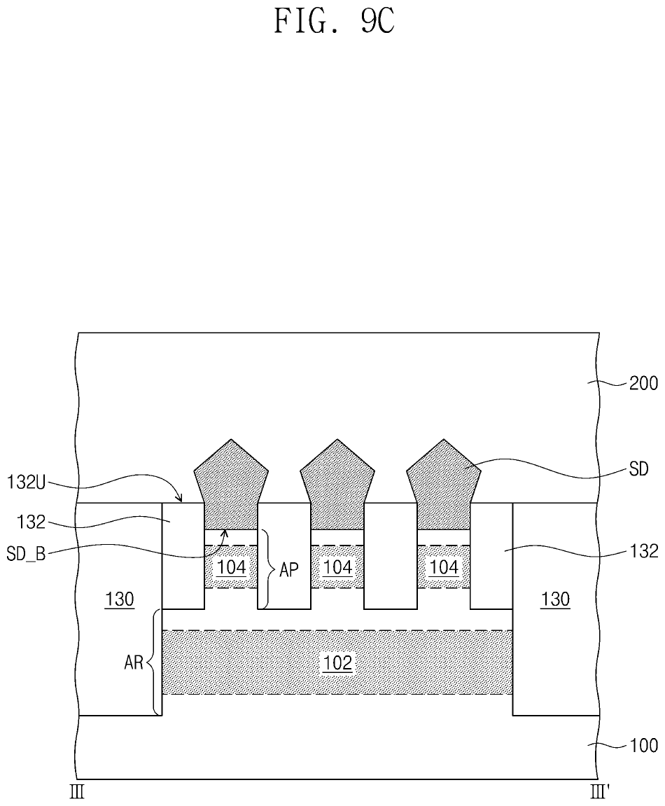

FIGS. 9A, 9B, and 9C are cross-sectional views respectively taken along lines I-I′, II-II′, and III-III′ of FIG. 1, illustrating a semiconductor device according to an exemplary embodiment of the present inventive concept. The following semiconductor device may be the same as or similar to that discussed with reference to FIGS. 1 and 2A to 2C, and thus the differences between the semiconductor devices may be described below and details may be omitted to the extent that they may be at least similar to corresponding elements already discussed.

Referring to FIGS. 1 and 9A to 9C, the barrier layer 120 may be interposed between the impurity layer 110 and the semiconductor pattern SP. Each of the source/drain patterns SD may contact the impurity layer 110 and/or the barrier layer 120. According to an exemplary embodiment of the present inventive concept, each of the source/drain patterns SD may penetrate the barrier layer 120 and the impurity layer 110. The lowermost bottom surface SD_B of each of the source/drain patterns SD may be located at a lower height than that of the bottom surface 1101 of the impurity layer 110 with respect to an upper surface of the substrate 100.

The second device isolation patterns 132 may be disposed on opposite sides of each of the active structures AS. For example, each of the second device isolation patterns 132 may be disposed between adjacent active structures AS. According to an exemplary embodiment of the present inventive concept, the second device isolation patterns 132 may expose the semiconductor pattern SP and an upper portion of each of the active patterns AP. The active fin AF may refer to the semiconductor pattern SP and the upper portion of each of the active patterns AP, which are exposed by the second device isolation patterns 132. The second device isolation patterns 132 may expose an upper portion of each of the source/drain patterns SD. The top surfaces 132U of the second device isolation patterns 132 may be located at a lower height than that of the top surface SP_U of the semiconductor pattern SP, and the second device isolation patterns 132 may expose the lateral surfaces SP_S of the semiconductor pattern SP and lateral surfaces of each of the active patterns AP.

The gate structure GS may extend in the second direction D2 and may cover the semiconductor pattern SP of each of the active structures AS. According to an exemplary embodiment of the present inventive concept, the gate structure GS may cover the top and lateral surfaces SP_U and SP_S of the semiconductor pattern SP and also cover the lateral surfaces of each of the active patterns AP. For example, the gate electrode GE may cover the top and lateral surfaces SP_U and SP_S of the semiconductor pattern SP and also cover the lateral surfaces of each of the active patterns AP. For example, the gate electrode GE may partially cover lateral surfaces of each of the active patterns AP. The gate dielectric pattern GI may be interposed between the gate electrode GE and the top surface SP_U of the semiconductor pattern SP and between the gate electrode GE and the lateral surfaces SP_S of the semiconductor pattern SP, and may extend between the gate electrode GE and the lateral surfaces of each of the active patterns AP.

According to an exemplary embodiment of the present inventive concept, each of the source/drain patterns SD may penetrate the impurity layer 110 and the barrier layer 120, and the lowermost bottom surface SD_B of each of the source/drain patterns SD may be located at a lower height than that of the bottom surface 110B of the impurity layer 110. In this case, the impurity layer 110 and the barrier layer 120 may suppress diffusion of the dopants having the second conductivity type in the source/drain patterns SD. As a result, it may be possible to suppress short channel effect and punch-through of the transistor.

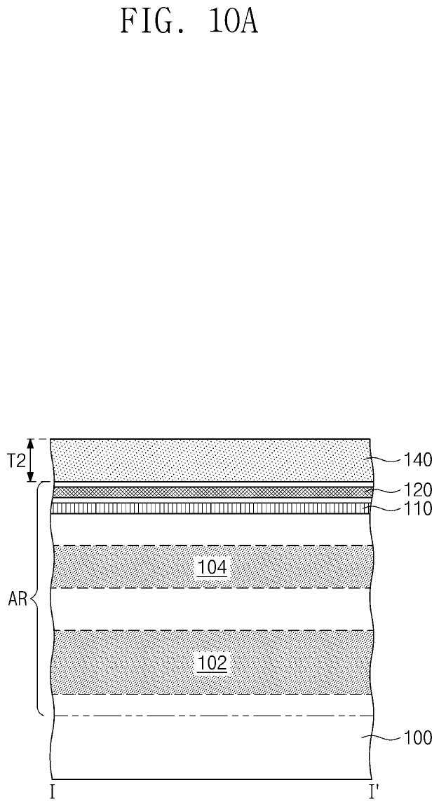

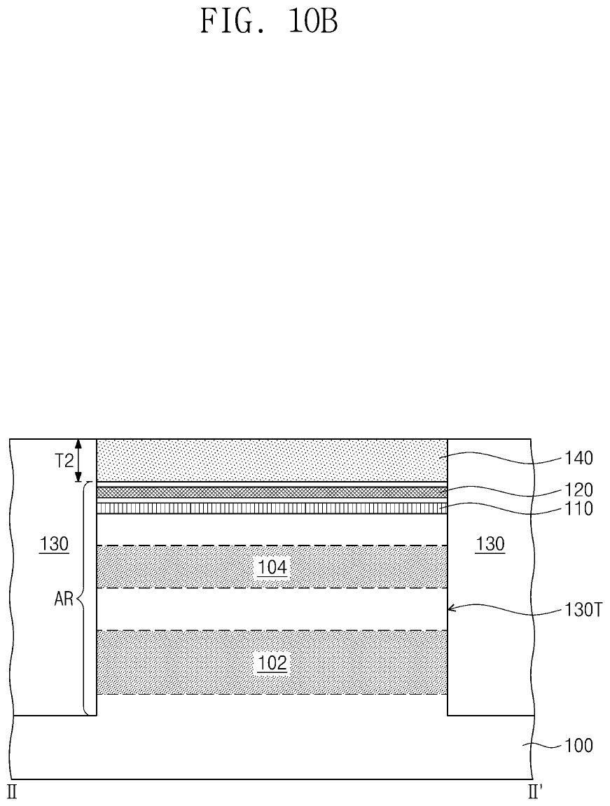

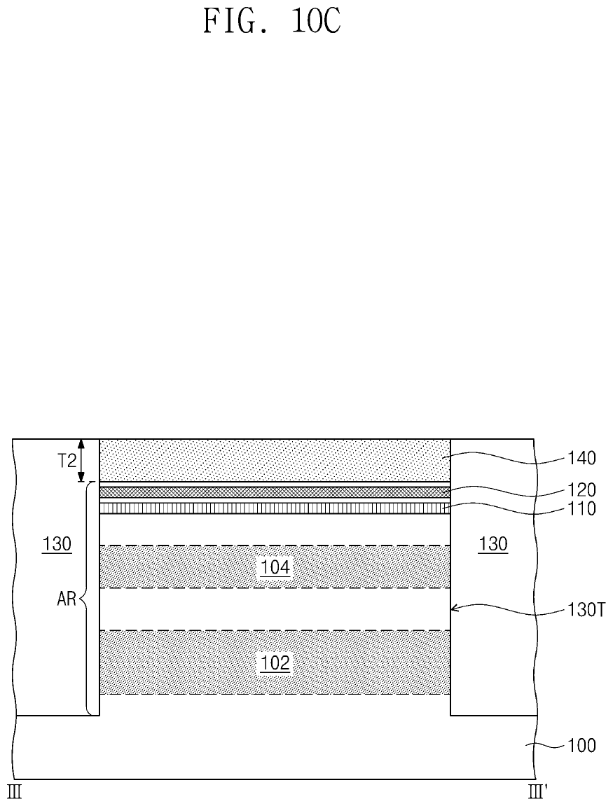

FIGS. 10A to 12A illustrate cross-sectional views taken along line I-I′ of FIG. 1, showing a method of manufacturing a semiconductor device according to an exemplary embodiment of the present inventive concept. FIGS. 10B to 12B illustrate cross-sectional views taken along line II-II′ of FIG. 1, showing a method of manufacturing a semiconductor device according to an exemplary embodiment of the present inventive concept. FIGS. 10C to 12C illustrate cross-sectional views taken along line III-III′ of FIG. 1, showing a method of manufacturing a semiconductor device according to an exemplary embodiment of the present inventive concept. The following semiconductor device may be the same as or similar to that discussed with reference to FIGS. 4A to 8A, 4B to 8B, and 4C to 8C, and thus the differences between the semiconductor devices may be described below in the interest of brevity of description.

Referring to FIGS. 1 and 10A to 10C, the semiconductor layer 140 may be formed on the substrate 100. The semiconductor layer 140 may include an intrinsic semiconductor material. According to an exemplary embodiment of the present inventive concept, the semiconductor layer 140 may have a relatively small thickness. For example, the semiconductor layer 140 may have a second thickness T2 less than the first thickness T1 (See, e.g., FIGS. 4A, 4B, and 4C).

The first trenches 130T may penetrate the semiconductor layer 140 and a portion of the substrate 100, and the first device isolation patterns 130 may be formed in corresponding first trenches 130T. The first trenches 130T may define the active region AR of the substrate 100. The first well region 102, the second well region 104, the impurity layer 110, and the barrier layer 120 may be sequentially disposed in the active region AR, and the semiconductor layer 140 may be disposed on the active region AR of the substrate 100.

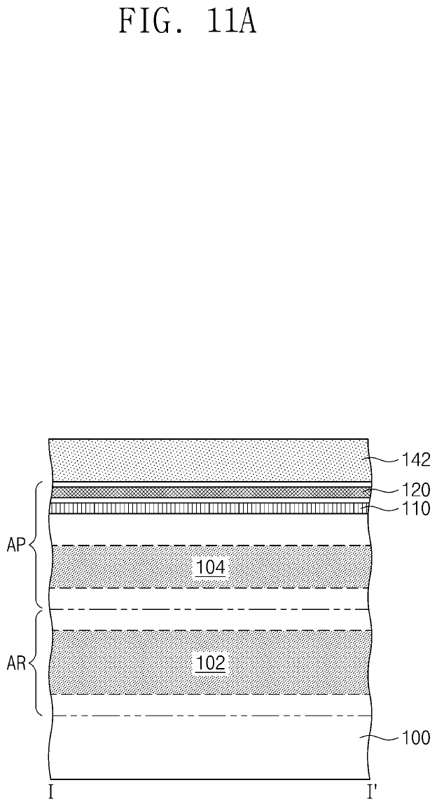

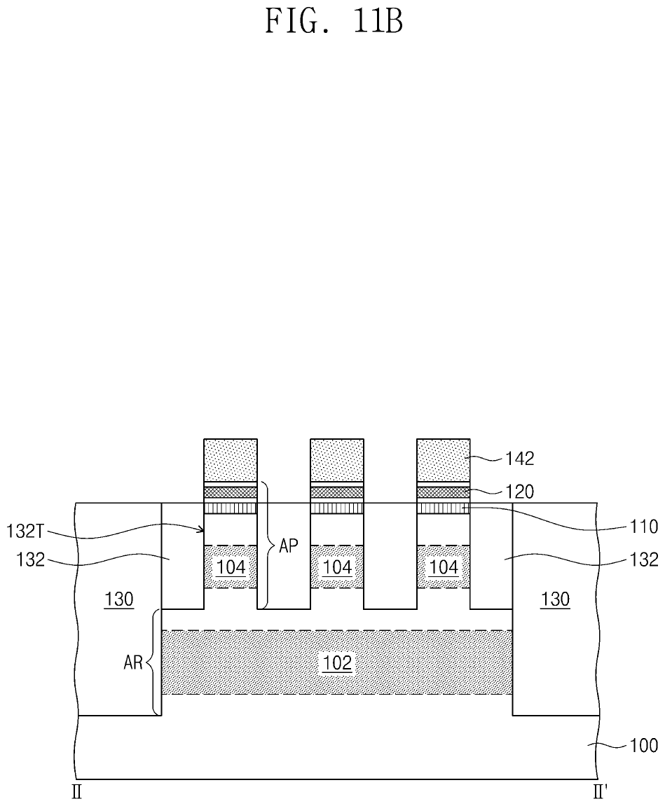

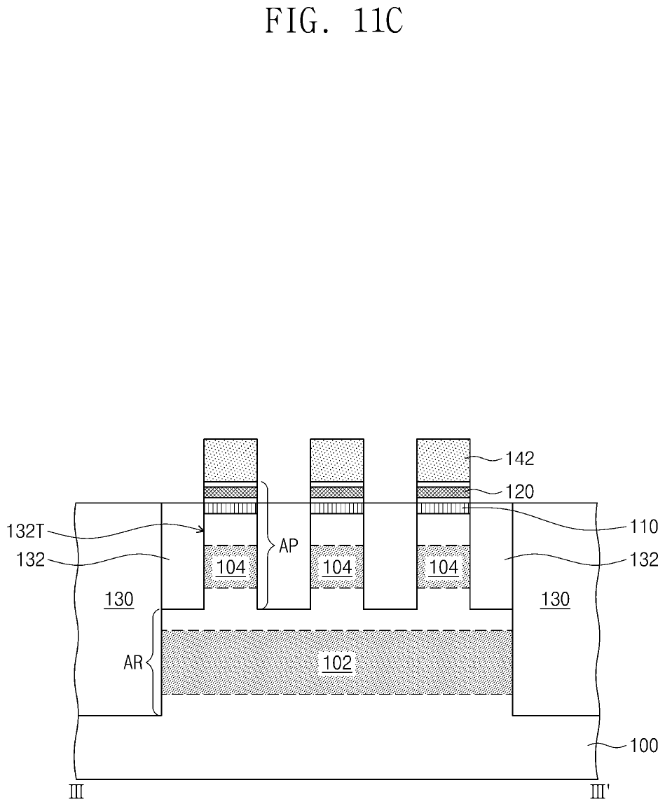

Referring to FIGS. 1 and 11A to 11C, the second trenches 132T may penetrate the semiconductor layer 140 and an upper portion of the active region AR, and the second device isolation patterns 132 may be formed in corresponding second trenches 132T. The second trenches 132T may separate the semiconductor layer 140 into the preliminary semiconductor patterns 142, and also separate the upper portion of the active region AR into the active patterns AP. Each of the active patterns AP may protrude upwardly from a lower portion of the active region AR. The preliminary semiconductor patterns 142 may be disposed on corresponding active patterns AP. According to an exemplary embodiment of the present inventive concept, upper portions of the first and second device isolation patterns 130 and 132 may be recessed and may expose the preliminary semiconductor patterns 142 and an upper portion of each of the active patterns AP.

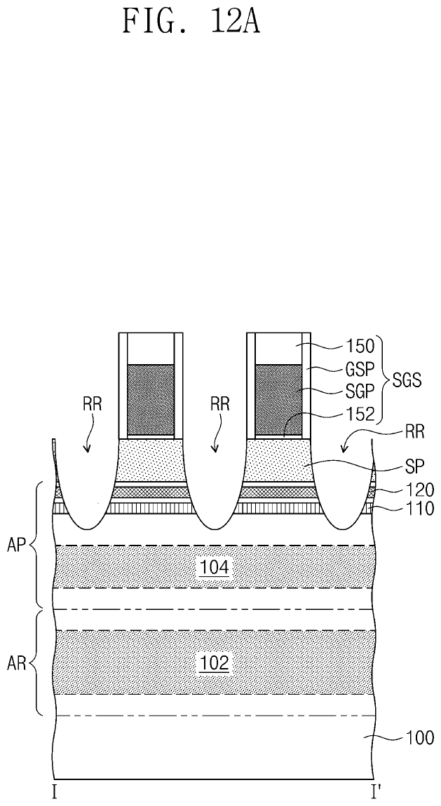

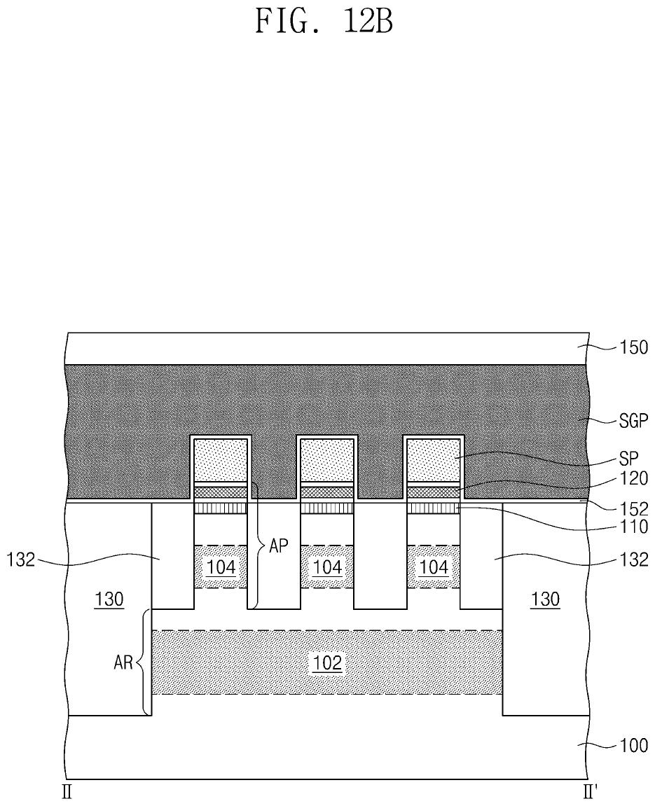

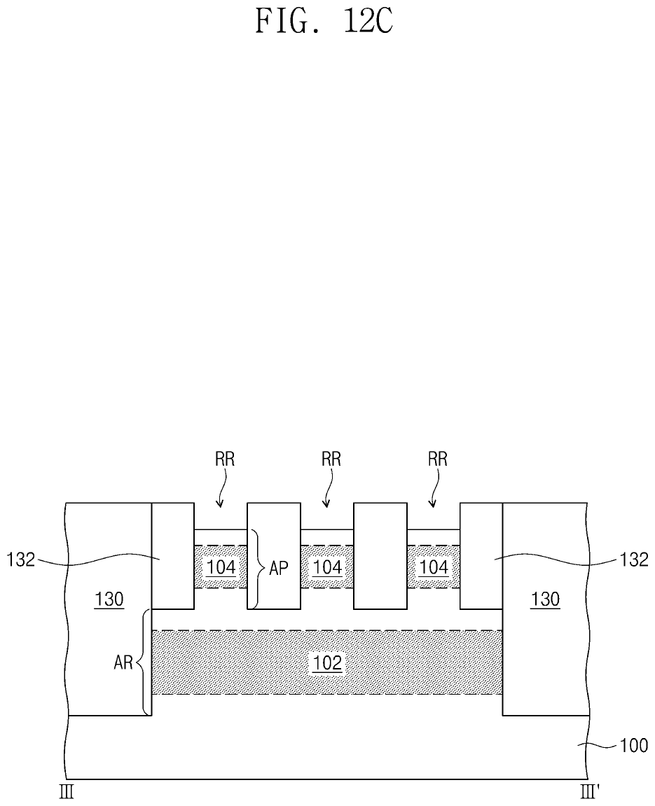

Referring to FIGS. 1 and 12A to 12C, the sacrificial gate structure SGS may extend across the preliminary semiconductor patterns 142 and the first and second device isolation patterns 130 and 132. For example, the sacrificial gate structure SGS may overlap the preliminary semiconductor patterns 142 and the first and second device isolation patterns 130 and 132. According to an exemplary embodiment of the present inventive concept, the sacrificial gate structure SGS may be used as an etching mask to pattern each of the preliminary semiconductor patterns 142 and the upper portion of each of the active patterns AP. Accordingly, the recess regions RR may be formed on opposite sides of the sacrificial gate structure SGS, and the semiconductor pattern SP may be formed below the sacrificial gate structure SGS. For example, the recess regions RR may be formed between each of the sacrificial gate structures SGS. The recess regions RR may expose lateral surfaces of the semiconductor pattern SP. According to an exemplary embodiment of the present inventive concept, because the semiconductor layer 140 is relatively thin (e.g., the second thickness T2), each of the recess regions RR may penetrate the impurity layer 110 and the barrier layer 120. For example, the recess regions may completely penetrate the impurity layer 110.

Subsequent processes may be the same as or similar to those discussed with reference to FIGS. 1, 7A to 7C, and 8A to 8C according to an exemplary embodiment of the present inventive concept.

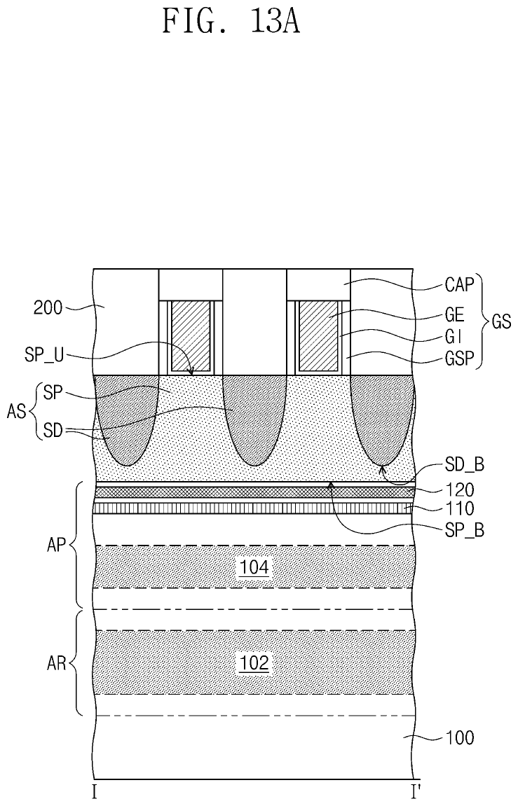

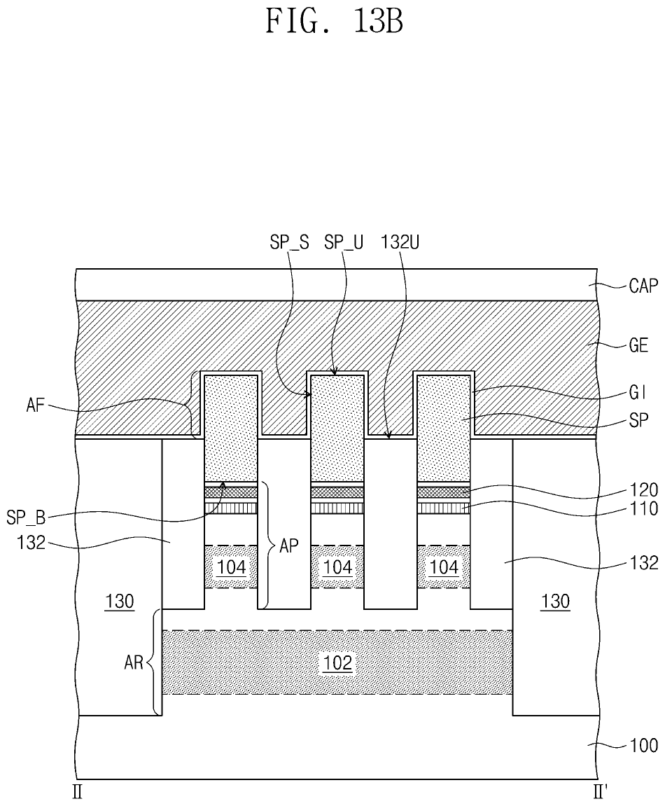

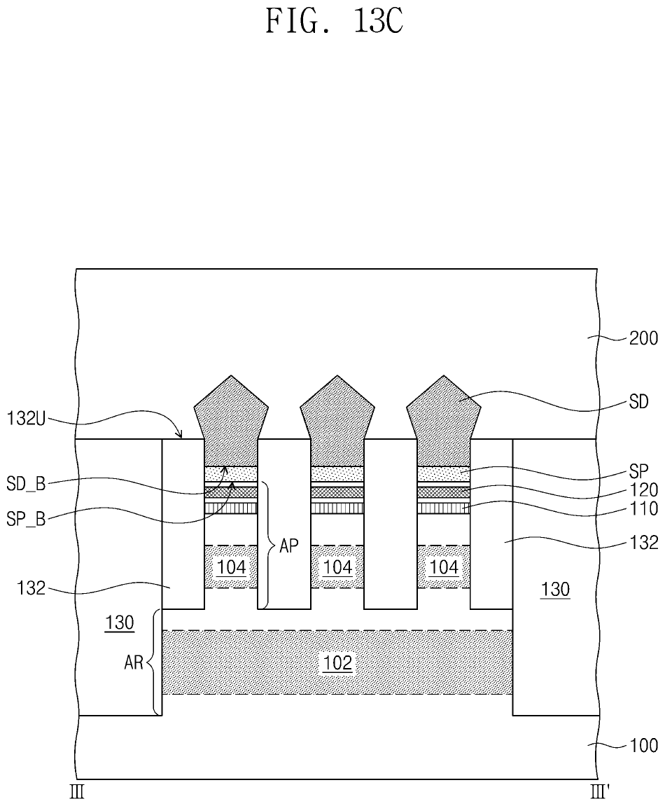

FIGS. 13A, 13B, and 13C are cross-sectional views respectively taken along lines I-I′, II-II′, and III-III′ of FIG. 1, showing a semiconductor device according to an exemplary embodiment of the present inventive concept. The following semiconductor device may be the same as or similar to that discussed with reference to FIGS. 1 and 2A to 2C, and thus the differences between the semiconductor devices will be described below and details may be omitted to the extent that they may be at least similar to corresponding elements already discussed.

Referring to FIGS. 1 and 13A to 13C, the active structures AS may be provided on the substrate 100. The active structures AS may be disposed on corresponding active patterns AP and may extend in the first direction D1. Each of the active structures AS may include the semiconductor pattern SP and the source/drain patterns SD. According to an exemplary embodiment of the present inventive concept, the semiconductor pattern SP may extend in the first direction D1, and each of the source/drain patterns SD may be disposed on the semiconductor pattern SP. The source/drain patterns SD may be spaced apart in the first direction D1 from each other across a portion of the semiconductor pattern SP. The semiconductor pattern SP may extend between each of the source/drain patterns SD. In addition, the semiconductor pattern SP may extend between the source/drain patterns SD and a corresponding one of the active patterns AP. For example, the source/drain patterns SD overlaps the active patterns AP. The lowermost bottom surface SD_B of each of the source/drain patterns SD may be located at a height between that of the top surface SP_U of the semiconductor pattern SP and that of a bottom surface SP_B of the semiconductor pattern SP.

The semiconductor pattern SP may be an epitaxial pattern grown from the substrate 100 serving as a seed. The semiconductor pattern SP may include an intrinsic semiconductor material. According to an exemplary embodiment of the present inventive concept, the source/drain patterns SD may be epitaxial patterns grown from the semiconductor pattern SP serving as a seed.

The barrier layer 120 may be interposed between the impurity layer 110 and the semiconductor pattern SP. According to an exemplary embodiment of the present inventive concept, the impurity layer 110 may extend between the second well region 104 and each of the source/drain patterns SD, and the barrier layer 120 may extend between the impurity layer 110 and each of the source/drain patterns SD. The semiconductor pattern SP may extend between the barrier layer 120 and each of the source/drain patterns SD. Each of the source/drain patterns SD may be spaced apart from the barrier layer 120 and the impurity layer 110 across at least a portion of the semiconductor pattern SP.

The second device isolation patterns 132 may be disposed on opposite sides of each of the active structures AS. For example, the second device isolation patterns 132 may be disposed between adjacent active structures AS. According to an exemplary embodiment of the present inventive concept, the second device isolation patterns 132 may expose an upper portion of the semiconductor pattern SP. In addition, the second device isolation patterns 132 may expose an upper portion of each of the source/drain patterns SD. The active fin AF may refer to the upper portion of the semiconductor pattern SP which is exposed by the second device isolation patterns 132. The semiconductor pattern SP may have a lower portion between adjacent second device isolation patterns 132.

According to an exemplary embodiment of the present inventive concept, each of the source/drain patterns SD may be spaced apart from the barrier layer 120 and the impurity layer 110. In this case, the source/drain patterns SD and the portion of the semiconductor pattern SP which is interposed between the source/drain patterns SD, may be less or minimally affected by dopants included in the barrier layer 120 and the impurity layer 110. Furthermore, the impurity layer 110 and the barrier layer 120 may suppress diffusion of the dopants having the second conductivity type in the source/drain patterns SD, and thus, it may be possible to suppress a short channel effect and diffusion of dopants from the transistor.

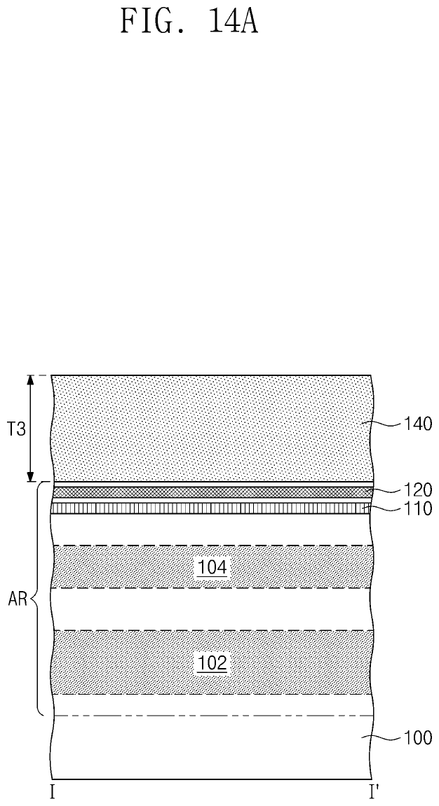

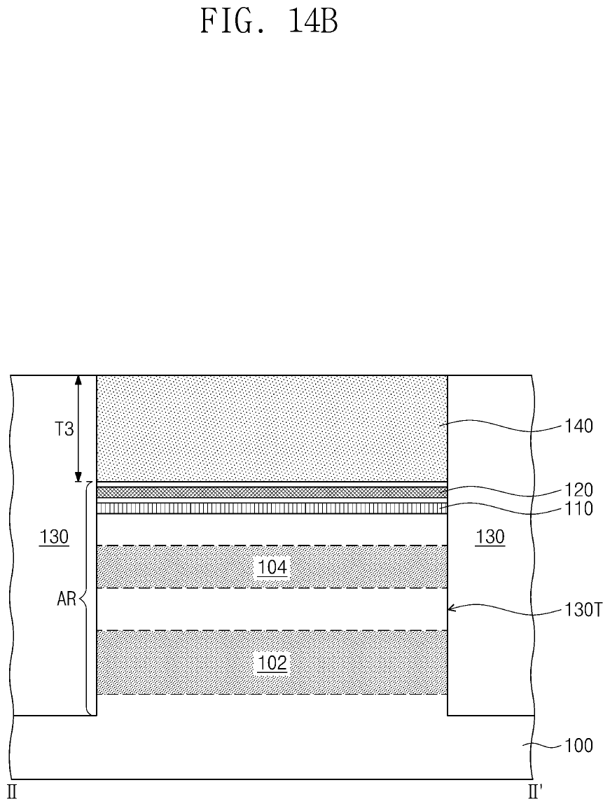

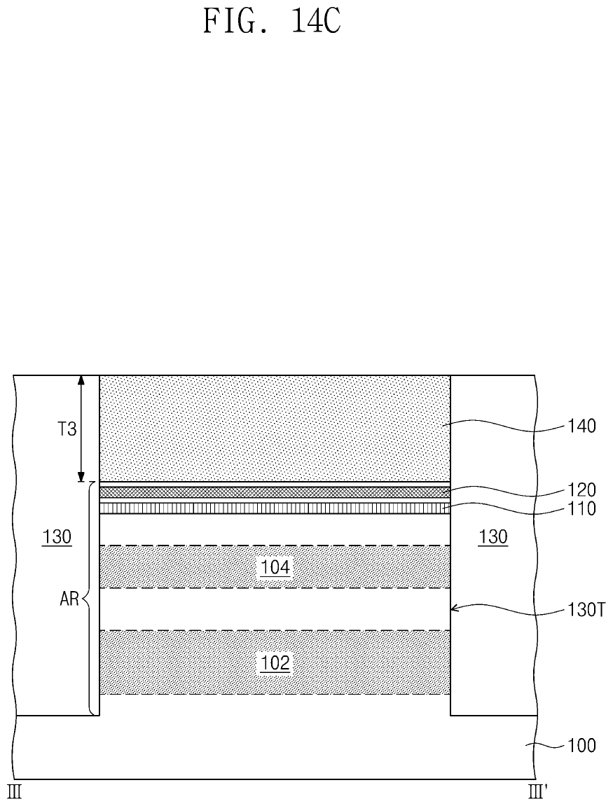

FIGS. 14A to 16A illustrate cross-sectional views taken along line I-I′ of FIG. 1, showing a method of manufacturing a semiconductor device according to an exemplary embodiment of the present inventive concept. FIGS. 14B to 16B illustrate cross-sectional views taken along line II-II′ of FIG. 1, showing a method of manufacturing a semiconductor device according to an exemplary embodiment of the present inventive concept. FIGS. 14C to 16C illustrate cross-sectional views taken along line III-III′ of FIG. 1, showing a method of manufacturing a semiconductor device according to an exemplary embodiment of the present inventive concept. The following semiconductor device may be the same as or similar to that discussed with reference to FIGS. 4A to 8A, 4B to 8B, and 4C to 8C, and thus the differences between the semiconductor devices will be described below in the interest of brevity of description.

Referring to FIGS. 1 and 14A to 14C, the semiconductor layer 140 may be formed on the substrate 100. The semiconductor layer 140 may include an intrinsic semiconductor material. According to an exemplary embodiment of the present inventive concept, the semiconductor layer 140 may be relatively thick. For example, the semiconductor layer 140 may have a third thickness T3 greater than the first thickness T1 (See, e.g., 4A, 4B, and 4C).

The first trenches 130T may penetrate the semiconductor layer 140 and a portion of the substrate 100, and the first device isolation patterns 130 may correspond to first trenches 130T. The first trenches 130T may define the active region AR of the substrate 100. The first well region 102, the second well region 104, the impurity layer 110, and the barrier layer 120 may be sequentially disposed in the active region AR of the substrate 100, and the semiconductor layer 140 may be disposed on the active region AR.

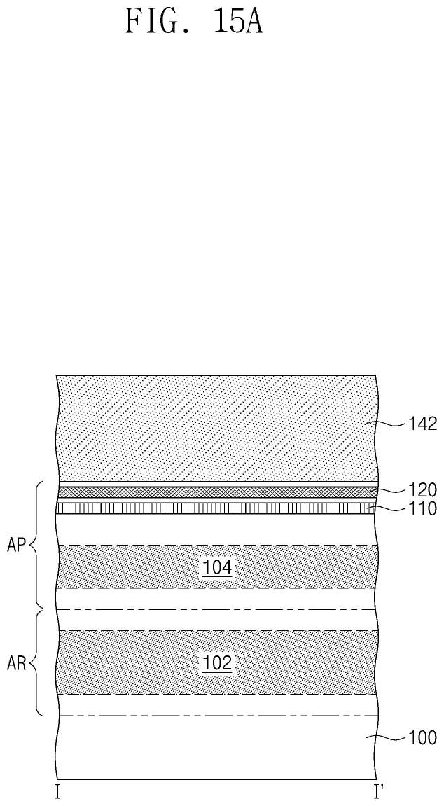

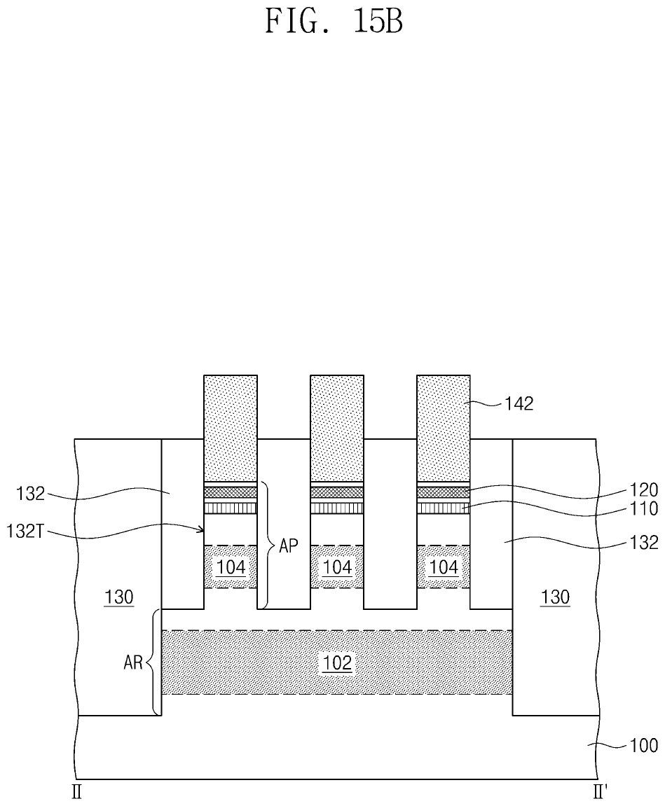

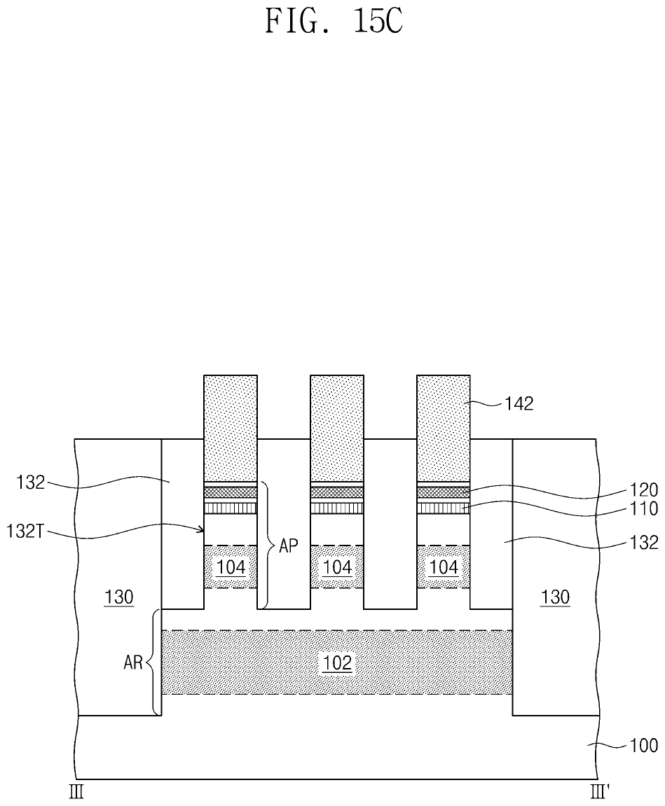

Referring to FIGS. 1 and 15A to 15C, the second trenches 132T may penetrate the semiconductor layer 140 and an upper portion of the active region AR, and the second device isolation patterns 132 may be formed in corresponding second trenches 132T. The second trenches 132T may separate the semiconductor layer 140 into the preliminary semiconductor patterns 142. In addition, the second trenches 132T may separate the upper portion of the active region AR into the active patterns AP. Each of the active patterns AP may protrude upwardly from a lower portion of the active region AR. For example, each of the active patterns AP may extend vertically with respect to an upper surface of the substrate 100. The preliminary semiconductor patterns 142 may be disposed on corresponding active patterns AP. According to an exemplary embodiment of the present inventive concept, upper portions of the first and second device isolation patterns 130 and 132 may be recessed to expose an upper portion of each of the preliminary semiconductor patterns 142. For example, a top surface and lateral surfaces of each of the preliminary semiconductor patterns 142 may be exposed.

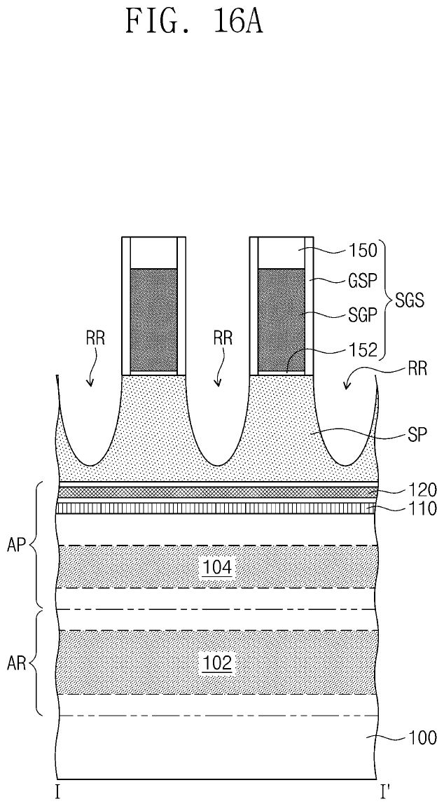

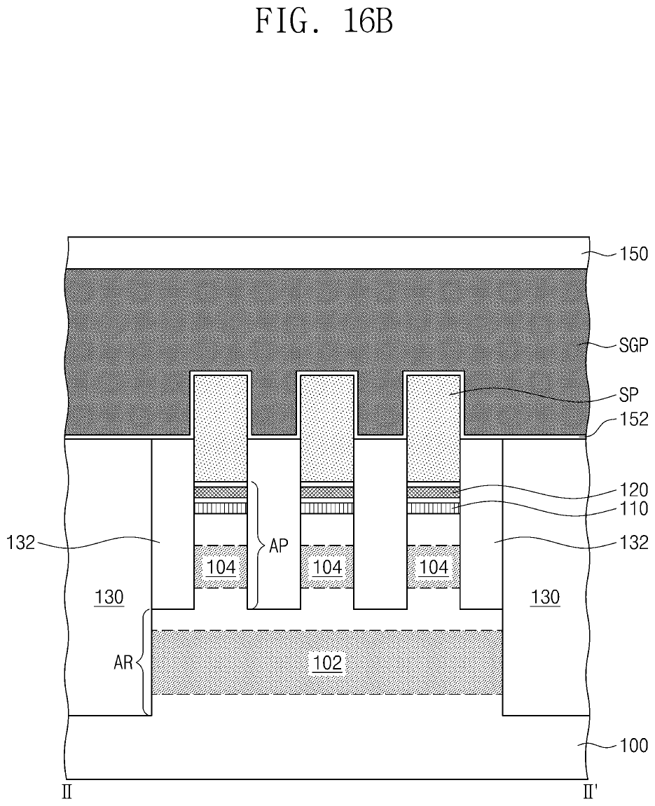

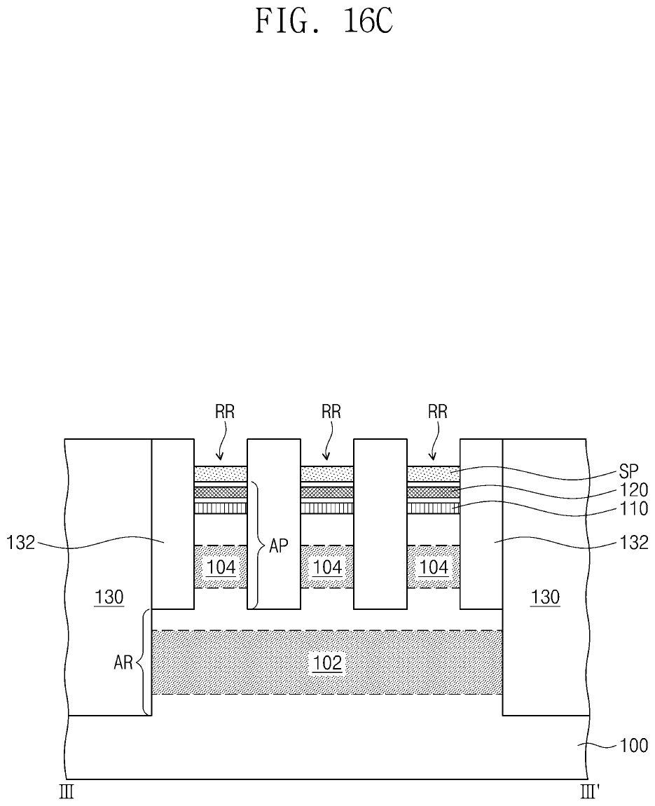

Referring to FIGS. 1 and 16A to 16C, the sacrificial gate structure SGS may extend across the preliminary semiconductor patterns 142 and the first and second device isolation patterns 130 and 132. According to an exemplary embodiment of the present inventive concept, the sacrificial gate structure SGS may be used as an etching mask to pattern the upper portion of each of the preliminary semiconductor patterns 142. Accordingly, the recess regions RR may be formed on opposite sides of the sacrificial gate structure SGS, and the semiconductor pattern SP may be formed below the sacrificial gate structure SGS. The semiconductor pattern SP may extend between each of the recess regions RR. In addition, the semiconductor pattern SP may extend between a corresponding one of the active patterns AP and the sacrificial gate structure SGS in, for example, a vertical direction with respect to the substrate 100. The recess regions RR may expose lateral surfaces of the semiconductor pattern SP. According to an exemplary embodiment of the present inventive concept, because the semiconductor layer 140 is relatively thick (e.g., the third thickness T3), each of the recess regions RR may be spaced apart from the impurity layer 110 and the barrier layer 120 across at least a portion of the semiconductor pattern SP.

Subsequent processes may be the same as or similar to those discussed with reference to FIGS. 1, 7A to 7C, and 8A to 8C.

According to an exemplary embodiment of the present inventive concept, the impurity layer 110 and the barrier layer 120 may be disposed adjacent to the semiconductor pattern SP and the source/drain patterns SD, and may suppress diffusion of the dopants having the second conductivity type in the source/drain patterns SD. Accordingly, it may be possible to suppress short channel effect of the transistor and to prevent diffusion between the source/drain patterns SD. Furthermore, as the semiconductor layer 140 may have a relatively small or large thickness, the source/drain patterns SD may penetrate the impurity layer 110 and the barrier layer 120, or may be spaced apart from the impurity layer 110 and the barrier layer 120. Therefore, a degree of which the source/drain patterns SD and the semiconductor pattern SP are affected by dopants may be controlled by the barrier layer 120 and the impurity layer 110.

According to an exemplary embodiment of the present inventive concept, an impurity layer and a barrier layer may be formed adjacent to a semiconductor pattern and source/drain patterns, and may suppress diffusion of dopants in the source/drain patterns. Accordingly, it may be possible to suppress a short channel effect of a transistor including the semiconductor pattern and the source/drain patterns, and to prevent punch-through between the source/drain patterns. For example, semiconductor devices may have improved electrical characteristics.

While the present inventive concept has been particularly shown and described with reference to exemplary embodiments thereof, it will be apparent to those of ordinary skill in the art that various changes in form and detail may be made thereto without departing from the spirit and scope of the present inventive concept.

1. A semiconductor device, comprising:
a substrate including a first well region;
a gate electrode disposed on the substrate;
a semiconductor pattern disposed between the substrate and the gate electrode;
a plurality of source/drain patterns disposed on the substrate and on opposing sides of the gate electrode;
an impurity layer disposed in the substrate and between the semiconductor pattern and the first well region; and
a barrier layer disposed in the substrate and between the semiconductor pattern and the impurity layer,
wherein the barrier layer includes oxygen.

2. The semiconductor device of claim 1, wherein the semiconductor pattern is disposed between the source/drain patterns and includes a semiconductor material.

3. The semiconductor device of claim 1, wherein the impurity layer and the first well region include impurities of a first conductivity type,
wherein an impurity concentration of the first conductivity type in the impurity layer is greater than an impurity concentration of the first conductivity type in the first well region.

4. The semiconductor device of claim 3, wherein an impurity concentration of the first conductivity type in an upper portion of the impurity layer is greater than an impurity concentration of the first conductivity type in a lower portion of the impurity layer,
wherein the upper portion of the impurity layer is closer than the lower portion of the impurity layer to the barrier layer.

5. The semiconductor device of claim 3, wherein the source/drain patterns include impurities having a second conductivity type,
wherein the impurities having the second conductivity type are different from the impurities having the first conductivity type.

6. The semiconductor device of claim 3, further comprising a second well region disposed in the substrate and between the first well region and the impurity layer,
wherein the second well region includes impurities having the first conductivity type.

7. The semiconductor device of claim 6, wherein the impurity concentration of the first conductivity type in the impurity layer is greater than an impurity concentration of the first conductivity type in the second well region.

8. The semiconductor device of claim 1, wherein each of the source/drain patterns contacts at least one of the impurity layer or the barrier layer.

9. The semiconductor device of claim 8, wherein each of the source/drain patterns penetrates the barrier layer and contacts the impurity layer.

10. The semiconductor device of claim 1, wherein the impurity layer is disposed between the first well region and each of the source/drain patterns.

11. The semiconductor device of claim 10, wherein the barrier layer is disposed between the impurity layer and each of the source/drain patterns.

12. The semiconductor device of claim 11, wherein the semiconductor pattern is disposed between the barrier layer and each of the source/drain patterns.

13. The semiconductor device of claim 1, further comprising a plurality of device isolation patterns disposed on the substrate and on corresponding opposite sides of the semiconductor pattern,
wherein the source/drain patterns are spaced apart in a first direction from each other across the semiconductor pattern,
wherein a first plurality of device isolation patterns of the plurality of device isolation patterns are spaced apart from each other in a second direction intersecting the first direction, wherein each of the device isolation patterns exposes a lateral surface of the semiconductor pattern, and
wherein the gate electrode extends in the second direction and covers a top surface and the exposed lateral surface of the semiconductor pattern.

14. A semiconductor device, comprising:
a substrate;
a gate electrode disposed on the substrate;
a semiconductor pattern disposed between the substrate and the gate electrode;
a plurality of source/drain patterns disposed on the substrate and on opposing sides of the gate electrode;
an impurity layer disposed in the substrate and adjacent to the semiconductor pattern; and
a barrier layer disposed in the substrate and between the semiconductor pattern and the impurity layer,
wherein the impurity layer includes impurities having a first conductivity type,
wherein an impurity concentration of the first conductivity type in an upper portion of the impurity layer is greater than an impurity concentration of the first conductivity type in a lower portion of the impurity layer.

15. The semiconductor device of claim 14, wherein the upper portion of the impurity layer is closer than the lower portion of the impurity layer to the barrier layer.

16. The semiconductor device of claim 14, wherein the barrier layer includes oxygen.

17. The semiconductor device of claim 14, wherein the source/drain patterns include impurities having a second conductivity type,
wherein the impurities having the second conductivity type are different from the impurities having the first conductivity type.

18-19. (canceled)

20. The semiconductor device of claim 14, further comprising a first well region and a second well region that are disposed in the substrate, wherein
the second well region is disposed between the first well region and the impurity layer,
the first well region and the second well region include impurities having the first conductivity type, and
an impurity concentration of the first conductivity type in the impurity layer is greater than an impurity concentration of the first conductivity type in the first well region and an impurity concentration of the first conductivity type in the second well region.

21. A semiconductor device, comprising:
a substrate;
a plurality of gate electrodes disposed on the substrate;
a semiconductor pattern disposed between the substrate and the gate electrodes;
a plurality of source/drain patterns disposed on the substrate, wherein each of the plurality of source/drain patterns is disposed between a pair of gate electrodes of the plurality of gate electrodes;
an impurity layer disposed in the substrate and including impurities having a first conductivity type; and
a barrier layer disposed in the substrate and between the semiconductor pattern and the impurity layer,
wherein the barrier layer is disposed adjacent to an upper surface of the impurity layer.

22. The semiconductor device of claim 21, wherein the impurity layer includes an upper portion adjacent to the upper surface of the impurity layer and a lower portion adjacent to a lower surface of the impurity layer, and the upper portion has an impurity concentration of the first conductivity type that is greater than that of the lower portion.
